(19) United States
(12) Patent Application Publication
(10) Pub. No.: US 2025/0330151 A1
(43) Pub. Date: Oct. 23, 2025

(54) ACOUSTIC WAVE DEVICE, RECEIVER AND COMMUNICATION DEVICE

(71) Applicant: Murata Manufacturing Co., Ltd., Nagaokakyo-shi (JP)

(72) Inventors: Minefumi OUCHI, Nagaokakyo-shi (JP); Hajime KANDO, Nagaokakyo-shi (JP)

(21) Appl. No.: 19/250,830

(22) Filed: Jun. 26, 2025

Related U.S. Application Data
(63) Continuation of application No. PCT/JP2023/045676, filed on Dec. 20, 2023.

(30) Foreign Application Priority Data
Dec. 27, 2022 (JP) 2022-209777

(51) Int. Cl. H03H 9/68; H01Q 1/24

(52) U.S. Cl. CPC H03H 9/68; H01Q 1/241

(57) ABSTRACT

An acoustic wave device includes an input I-terminal and an input Q-terminal to respectively receive an I signal and a Q signal with a phase difference of about 90°, an output terminal, an acoustic wave phase shift circuit connected between the input I-terminal and the output terminal, including an acoustic wave resonator, and to adjust a phase of the I signal, an acoustic wave phase shift circuit connected between the input Q-terminal and the output terminal, including an acoustic wave resonator, and to adjust a phase of the Q signal, and a phase compensator connected to at least one of between the input I-terminal and the acoustic wave phase shift circuit, between the input Q-terminal and the acoustic wave phase shift circuit, between the output terminal and the acoustic wave phase shift circuit, and between the output terminal and the acoustic wave phase shift circuit.

### CROSS REFERENCE TO RELATED APPLICATIONS

This application claims the benefit of priority to Japanese Patent Application No. 2022-209777 filed on Dec. 27, 2022 and is a Continuation application of PCT Application No. PCT/JP2023/045676 filed on Dec. 20, 2023. The entire contents of each application are hereby incorporated herein by reference.

### BACKGROUND OF THE INVENTION

### 1. Field of the Invention

The present invention relates to acoustic wave devices, receivers, and communication devices.

### 2. Description of the Related Art

“A 2.5 to 4.5 GHz Switched-LC-Mixer-First Acoustic-Filtering RF Front-End Achieving <6 dB NF, +30 dBm IIP3 at 1×Bandwidth Offset”, H. Seo and J. Zhou, IEEE RFIC, 2020, pp. 283-286 discloses a mixer-first type acoustic filtering front-end circuit (receiver) having a mixer (N-Path Switched-LC Mixer) disposed in the subsequent stage of an antenna, and an acoustic filter disposed in the subsequent stage of the mixer. Specifically, Fig. 5 of “A 2.5 to 4.5 GHz Switched-LC-Mixer-First Acoustic-Filtering RF Front-End Achieving <6 dB NF, +30 dBm IIP3 at 1×Bandwidth Offset”, H. Seo and J. Zhou, IEEE RFIC, 2020, pp. 283-286 illustrates a receiver having a quadrature mixer composed of a differential input-differential output Gilbert cell mixer in the subsequent stage of a signal input terminal (RF Input), a 90° phase shifter and a balun disposed in the subsequent stage of the Q-path of the quadrature mixer, and a surface acoustic wave (SAW) band pass filter disposed in the subsequent stage of the balun.

A differential signal inputted from the signal input terminal is divided into an I-path and a Q-path, and inputted to the quadrature mixer. In the quadrature mixer, the signals are modulated, by mixers disposed in the I-path and the Q-path respectively, into intermediate frequency signals (IF signals) having a phase difference of about 90° between the I-path and the Q-path. Further, by performing phase rotation with the balun disposed in the subsequent stage of the quadrature mixer and the 90° phase shifter disposed in the Q-path, a desired signal in the Q-path is in opposite phase to a desired signal in the I-path, and an image signal in the Q-path is in phase with an image signal in the I-path. By combining the desired signals and the image signals with the balun, the image signals in phase are canceled out, and the desired signals in opposite phase are extracted, converted to a non-differential signal, and outputted. Thus, by passing a plurality of radio-frequency signals having different frequency bands through a single surface acoustic wave band pass filter (acoustic wave device) disposed in the subsequent stage of the quadrature mixer, it is possible to perform receive processing on the radio-frequency signals with low loss.

However, in the receiver of “A 2.5 to 4.5 GHz Switched-LC-Mixer-First Acoustic-Filtering RF Front-End Achieving <6 dB NF, +30 dBm IIP3 at 1×Bandwidth Offset”, H. Seo and J. Zhou, IEEE RFIC, 2020, pp. 283-286, it is required to provide, between the output end of the mixer and the input end of the acoustic wave device, a plurality of baluns and LC circuits for performing phase conversion and balance/non-balance conversion, so that the circuit becomes large.

Further, when the differential signal has a predetermined frequency band, it is not easy to maintain a constant phase difference relationship between the I signal and the Q signal over the predetermined frequency band with low loss and high accuracy.

### SUMMARY OF THE INVENTION

Example embodiments of the present invention provide acoustic wave devices each having a smaller size and able to perform phase adjustment with low loss and high accuracy, and also provide mixer-first receivers, and communication devices.

An acoustic wave device according to an example embodiment of the present invention includes an I signal terminal and a Q signal terminal to respectively receive an I signal and a Q signal with a phase difference of 90° from each other, an output terminal, a first phase shift circuit connected between the I signal terminal and the output terminal, including an acoustic wave resonator, and to adjust a phase of the I signal, a second phase shift circuit connected between the Q signal terminal and the output terminal, including an acoustic wave resonator, and to adjust a phase of the Q signal, and a phase compensator connected to at least one of between the I signal terminal and the first phase shift circuit, between the Q signal terminal and the second phase shift circuit, between the output terminal and the first phase shift circuit, and between the output terminal and the second phase shift circuit.

According to example embodiments of the present invention, it is possible to provide acoustic wave devices each with a smaller size and able to perform phase adjustment with low loss and high accuracy, mixer-first receivers, and communication devices.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit configuration diagram of a receiver and a communication device according to an example embodiment of the present invention.

FIG. 2A is a diagram showing an example of an electrode configuration of a longitudinally coupled SAW filter according to an example embodiment of the present invention.

FIG. 2B is a diagram showing a schematic representation of a longitudinally coupled SAW filter according to an example embodiment of the present invention.

FIG. 3 is a circuit configuration diagram of an acoustic wave device according to Example 1 of an example embodiment of the present invention.

FIG. 4A is a circuit configuration diagram of a receiver according to Modification 1 of an example embodiment of the present invention.

FIG. 4B is a timing chart showing driving signals of a quadrature mixer according to Modification 1 of an example embodiment of the present invention.

FIG. 5 is a circuit configuration diagram of an acoustic wave device according to Modification 1 of an example embodiment of the present invention.

FIG. 6A is a graph showing the bandpass characteristics of an acoustic wave device according to a comparative example.

FIG. 6B is a graph showing the bandpass characteristics of the acoustic wave device according to Modification 1 of an example embodiment of the present invention.

FIG. 7A is a graph showing the phase characteristics of the acoustic wave device according to the comparative example.

FIG. 7B is a graph showing the phase characteristics of the I signal in the acoustic wave device according to Modification 1 of an example embodiment of the present invention and the acoustic wave device according to the comparative example.

FIG. 8 is a graph showing the characteristics of the phase difference between the I signal and the Q signal in the acoustic wave device according to Modification 1 of an example embodiment of the present invention and the acoustic wave device according to the comparative example.

FIG. 9 is a circuit configuration diagram of an acoustic wave device according to Modification 2 of an example embodiment of the present invention.

FIG. 10 is a circuit configuration diagram of an acoustic wave device according to Modification 3 of an example embodiment of the present invention.

FIG. 11 is a circuit configuration diagram of an acoustic wave device according to Modification 4 of an example embodiment of the present invention.

FIG. 12 is a circuit configuration diagram of an acoustic wave device according to Modification 5 of an example embodiment of the present invention.

FIG. 13 is a circuit configuration diagram of an acoustic wave device according to Modification 6 of an example embodiment of the present invention.

FIG. 14 is a circuit configuration diagram of an acoustic wave phase shift circuit according to Modification 7 of an example embodiment of the present invention.

### DETAILED DESCRIPTION OF THE EXAMPLE EMBODIMENTS

Example embodiments of the present invention will be described in detail below with reference to the drawings. All of the example embodiments described below are comprehensive or specific examples. The numerical values, shapes, materials, components, arrangement of components, connection configurations and the like shown in the following example embodiments are examples and are not intended to limit the present invention. Among the components in the following examples and modifications, component(s) not described in the independent claims are described as optional component(s). Also, the size or size ratio of the components shown in the drawings is not necessarily strictly illustrated.

Further, in the example embodiments to be described below, the term “signal path” means a transmission line including a wire through which a high frequency signal propagates, circuit elements and electrodes directly connected to the wire, terminals directly connected to the wire or the electrodes, and/or the like.

Further, in the example embodiments to be described below, the term “connected” includes not only directly connected by connection terminals and/or wiring conductors, but also electrically connected via other circuit elements. Further, the expression “connected between A and B” means “connected to both A and B on a path connecting A and B”, and includes “connected in (shunt) between a path connecting A and B and ground”, in addition to “connected in series with the path”.

Further, in the example embodiments to be described below, the expression “the component A is arranged in series in the path B” means that both the signal input end and the signal output end of the component A are connected to the wire, the electrodes, or the terminals constituting the path B.

Further, in the following description, a configuration where two signals are in phase means that the phases of the two signals are within a range in which the phases of the two signals can be considered substantially equivalent to each other, for example, with a phase difference of several percent. Further, a configuration where two signals are in opposite phase to each other means that the phase difference between the two signals is substantially 180°, for example, when the phase difference is 180° plus or minus several percent.

### EXAMPLE EMBODIMENTS

### 1. Circuit Configuration of Receiver 1 and Communication Device 5

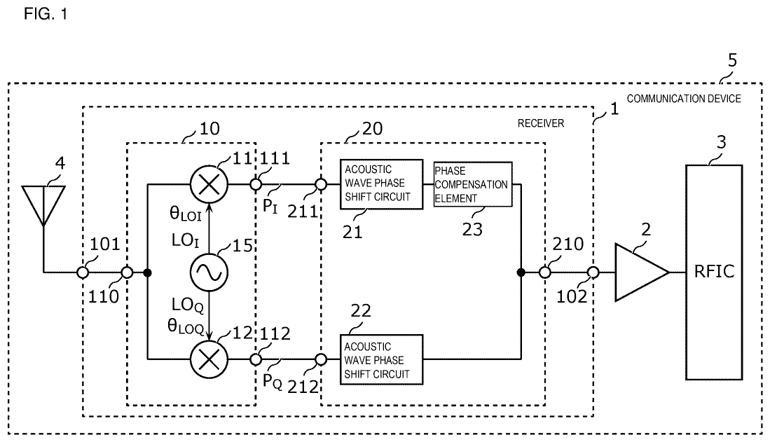

Circuit configurations of a receiver 1 and a communication device 5 according to an example embodiment of the present invention will be described with reference to FIG. 1. FIG. 1 is a circuit configuration diagram of the receiver 1 and the communication device 5 according to the present example embodiment.

### 1.1 Circuit Configuration of Communication Device 5

First, the circuit configuration of the communication device 5 will be described. As shown in FIG. 1, the communication device 5 according to the present example embodiment includes the receiver 1, a low-noise amplifier 2, an RF signal processing circuit (RFIC) 3, and an antenna 4.

The receiver 1 transmits a radio-frequency signal between the antenna 4 and the RFIC 3. The detailed circuit configuration of the receiver 1 will be described later.

The low-noise amplifier 2 amplifies the radio-frequency signal outputted from a signal output terminal 102 of the receiver 1. The input end of the low-noise amplifier 2 is connected to the signal output terminal 102, and the output end of the low-noise amplifier 2 is connected to the RFIC 3.

The antenna 4 is connected to an antenna connection terminal 101 of the receiver 1. The antenna 4 receives a radio-frequency signal from the outside, and outputs the radio-frequency signal to the receiver 1.

The RFIC 3 is an example of a signal processing circuit to process radio-frequency signals. Specifically, the RFIC 3 performs signal processing on a received signal inputted via a reception path of the receiver 1, and outputs a received signal generated by performing the signal processing to a baseband signal processing circuit (BBIC, not shown) or the like. The RFIC 3 also includes a controller configured or programmed to control switches and the like of the receiver 1 based on the band (frequency band) information of the radio-frequency signal transmitted by the receiver 1. Some or all of the functions of the controller of the RFIC 3 may be provided outside the RFIC 3, for example, in the BBIC or the receiver 1.

Also, in the communication device 5 according to the present example embodiment, the antenna 4 is not an essential component.

Alternatively, the communication device 5 may include a transmitter that outputs a radio-frequency signal, which has been signal-processed by the RFIC 3, to the antenna 4. In such a case, the RFIC 3 performs signal processing, by up-converting or the like, on a transmission signal inputted from the BBIC, and outputs a transmission signal generated by performing the signal processing to the transmitter.

### 1.2 Circuit Configuration of Receiver 1

Next, the circuit configuration of the receiver 1 will be described. As shown in FIG. 1, the receiver 1 includes a quadrature mixer 10, an acoustic wave device 20, the antenna connection terminal 101, and the signal output terminal 102.

The quadrature mixer 10 includes mixers 11 and 12, a local oscillation circuit 15, an input terminal 110, an output I-terminal 111, and an output Q-terminal 112.

The mixer 11 is an example of a first mixer. The mixer 11 performs frequency conversion to convert the radio-frequency signal inputted from the input terminal 110 into an I signal, and outputs the I signal from the output I-terminal 111. The mixer 12 is an example of a second mixer. The mixer 12 performs frequency conversion to convert the radio-frequency signal inputted from the input terminal 110 into a Q signal having a phase difference of about 90° from the I signal, and outputs the Q signal from the output Q-terminal 112. In other words, the quadrature mixer 10 performs frequency conversion to convert the radio-frequency signal into an I signal and a Q signal having a phase difference of about 90° from each other.

The acoustic wave device 20 includes acoustic wave phase shift circuits 21 and 22, a phase compensator 23, an input I-terminal 211 (I signal terminal) an input Q-terminal 212 (Q signal terminal), and an output terminal 210. The input I-terminal 211 is connected to the output I-terminal 111, and the input Q-terminal 212 is connected to the output Q-terminal 112. The input I-terminal 211 (I signal terminal) and the input Q-terminal 212 (Q signal terminal) receive the I signal and the Q signal having a phase difference of about 90° from each other, respectively.

The acoustic wave phase shift circuit 21 is an example of a first phase shift circuit. The acoustic wave phase shift circuit 21 is connected between the input I-terminal 211 and the output terminal 210, includes an acoustic wave resonator, and adjusts the phase of the I signal transmitted through a path P_{I} connecting the mixer 11 and the acoustic wave phase shift circuit 21. The acoustic wave phase shift circuit 22 is an example of a second phase shift circuit. The acoustic wave phase shift circuit 22 is connected between the input Q-terminal 212 and the output terminal 210, includes an acoustic wave resonator, and adjusts the phase of the Q signal transmitted through a path P_{Q} connecting the mixer 12 and the acoustic wave phase shift circuit 22. Each of the acoustic wave phase shift circuits 21 and 22 includes, for example, a SAW resonator.

The acoustic wave phase shift circuit 21 defines a filter circuit whose pass band includes the frequency of the I signal. The acoustic wave phase shift circuit 22 defines a filter circuit whose pass band includes the frequency of the Q signal.

The acoustic wave phase shift circuit 21 and the acoustic wave phase shift circuit 22 need not necessarily be configured separately, but may alternatively be provided as a single unit, for example, in a manner in which an IDT (Interdigital Transducer) electrode connected to the input I-terminal 211, an IDT electrode connected to the input Q-terminal 212, and an IDT electrode connected to the output terminal 210 are provided in a single acoustic wave propagation path.

The phase compensator 23 is connected between the acoustic wave phase shift circuit 21 and the output terminal 210, and compensates the phase of the I signal that has passed through the acoustic wave phase shift circuit 21. The phase compensator 23 is, for example, an acoustic wave resonator. When the acoustic wave phase shift circuits 21 and 22 each include a SAW resonator, it is preferable that the phase compensator 23 is also a SAW resonator.

The phase compensator 23 may be connected to at least one of (1) between the input I-terminal 211 and the acoustic wave phase shift circuit 21, (2) between the input Q-terminal 212 and the acoustic wave phase shift circuit 22, (3) between the output terminal 210 and the acoustic wave phase shift circuit 21, and (4) between the output terminal 210 and the acoustic wave phase shift circuit 22.

### 1.3 Operating Principle of Receiver 1

The operating principle of the receiver 1 according to the present example embodiment will be described below.

The receiver 1 performs frequency conversion processing and phase conversion processing on a radio-frequency signal having a frequency F_{RF} inputted from the antenna connection terminal 101, and outputs the radio-frequency signal to the low-noise amplifier 2 and RFIC 3 with low loss. In a conventional receiver, in order to perform receive processing on radio-frequency signals of multiple bands, a plurality of reception filters corresponding to the frequencies of the radio-frequency signals are required. In contrast, in the receiver 1 according to the present example embodiment, since a plurality of radio-frequency signals having different frequencies F_{RF} are converted into signals having a desired frequency, receive processing can be performed by a single reception filter corresponding to the desired frequency.

The radio-frequency signal including a desired signal D and an image signal IM is inputted to the input terminal 110 and distributed to the mixers 11 and 12. At this time, a desired signal D_{I} and an image signal IM_{I} inputted to the mixer 11 are modulated to frequencies (−F_{IF}) and (+F_{IF}), respectively, and the desired signal D_{I} and the image signal IM_{I} are in phase. On the other hand, a desired signal D_{Q} and an image signal IM_{Q} inputted to the mixer 12 are modulated to frequencies (−F_{IF}) and (+F_{IF}), respectively, and the desired signal D_{Q} is rotated about 90° (or about −90°) with respect to the desired signal D_{I}, and the image signal IM_{Q} is rotated about −90° (or about 90°) with respect to the image signal IM_{I}. The following description will be made using mathematical expressions.

When a local signal outputted from the local oscillation circuit 15 to the mixer 11 is defined as LO_{I}, and a local signal outputted from the local oscillation circuit 15 to the mixer 12 is defined as LO_{Q}, the desired signals D_{I} and D_{Q}, the image signals IM_{I} and IM_{Q}, and local signals LO_{I} and LO_{Q} are expressed as Expressions 1 and 2, respectively.

$$D = {D}_{I} + {D}_{Q} \qquad ( Expression 1 )$$

$$IM = {IM}_{I} + {IM}_{Q}$$

$${ω}_{RF} = {ω}_{LO} + {ω}_{IF} , {F}_{RF} = {F}_{LO} + {F}_{IF}$$

$${ω}_{IM} = {ω}_{LO} - {ω}_{IF} , {F}_{IM} = {F}_{LO} - {F}_{IF}$$

$${D}_{I} = {D}_{Q} = {A}_{RF} \frac{{e}^{j ( {ω}_{LO} + {ω}_{IF} ) t} + {e}^{- j ( {ω}_{LO} + {ω}_{IF} ) t}}{2} \qquad ( Expression 2 )$$

$${IM}_{I} = {IM}_{Q} = {A}_{IM} \frac{{e}^{j ( {ω}_{LO} - {ω}_{IF} ) t} + {e}^{- j ( {ω}_{LO} - {ω}_{IF} ) t}}{2}$$

$${LO}_{I} = \frac{{e}^{j {ω}_{LO} t} + {e}^{- j {ω}_{LO} t}}{2}$$

$${LO}_{Q} = \frac{- {e}^{j {ω}_{LO} t} + {e}^{- j {ω}_{LO} t}}{2 j}$$

When the desired signal D_{I} and the local signal LO_{I} are multiplied by the mixer 11 and the radio-frequency component of (2ω_{LO}+ω_{IF}) is ignored, a desired signal D_{I}LO_{I} outputted from the mixer 11 is expressed as Expression 3.

$${D}_{I} {LO}_{I} = \frac{{A}_{RF}}{2} cos {ω}_{IF} t \qquad ( Expression 3 )$$

Similarly, when the image signal IM_{I} and the local signal LO_{I} are multiplied by the mixer 11 and the radio-frequency component is ignored, an image signal IM_{I}LO_{I} outputted from the mixer 11 is expressed as Expression 4.

$${IM}_{I} {LO}_{I} = \frac{{A}_{IM}}{2} cos {ω}_{IF} t \qquad ( Expression 4 )$$

As expressed as Expressions 3 and 4, the desired signal D_{I}LO_{I} and the image signal IM_{I}LO_{I} of the path P_{I} are both converted into signals in an IF band in phase, and outputted from the mixer 11.

Further, when the desired signal D_{Q} and the local signal LO_{Q} are multiplied by the mixer 12 and the radio-frequency component is ignored, a desired signal D_{Q}LO_{Q} outputted from the mixer 12 is expressed as Expression 5.

$${D}_{Q} {LO}_{Q} = \frac{{A}_{RF}}{2} sin {ω}_{IF} t \qquad ( Expression 5 )$$

Similarly, when the image signal IM_{Q} and the local signal LO_{Q} are multiplied by the mixer 12 and the radio-frequency component is ignored, an image signal IM_{Q}LO_{Q} outputted from the mixer 12 is expressed as Expression 6.

$${IM}_{Q} {LO}_{Q} = - \frac{{A}_{IM}}{2} sin {ω}_{IF} t \qquad ( Expression 6 )$$

As expressed as Expressions 5 and 6, the desired signal D_{Q}LO_{Q} and the image signal IM_{Q}LO_{Q} of the path P_{Q} are both converted into signals in an IF band in opposite phase to each other, and outputted from the mixer 12.

The desired signal D_{I}LO_{I} and the image signal IM_{I}LO_{I} transmitted through the path P_{I} are inputted to the input I-terminal 211, phase-adjusted by the acoustic wave phase shift circuit 21, filtered as necessary, and outputted to the output terminal 210. The phases of the desired signal D_{I}LO_{I} and the image signal IM_{I}LO_{I} outputted from the acoustic wave phase shift circuit 21 are, for example, about 0° (no phase rotation) and are in phase. Therefore, assuming that the conversion gain in the acoustic wave phase shift circuit 21 is B_{SAW}, the desired signal D_{I}LO_{I} outputted from the acoustic wave phase shift circuit 21 is expressed as Expression 7, and the image signal IM_{I}LO_{I} outputted from the acoustic wave phase shift circuit 21 is expressed as Expression 8.

$${D}_{I} {LO}_{I} = {B}_{SAW} \frac{{A}_{RF}}{2} cos {ω}_{IF} t \qquad ( Expression 7 )$$

$${IM}_{I} {LO}_{I} = {B}_{SAW} \frac{{A}_{IM}}{2} cos {ω}_{IF} t \qquad ( Expression 8 )$$

On the other hand, the desired signal D_{Q}LO_{Q} and the image signal IM_{Q}LO_{Q} transmitted through the path P_{Q} are inputted to the input Q-terminal 212, phase-adjusted by the acoustic wave phase shift circuit 22, filtered as necessary, and outputted to the output terminal 210. The phases of the desired signal D_{Q}LO_{Q} and the image signal IM_{Q}LO_{Q} outputted from the acoustic wave phase shift circuit 22 are, for example, both rotated by about 90°, so that the phase of the desired signal D_{Q}LO_{Q} becomes about 0° and the phase of the image signal IM_{Q}LO_{Q} becomes about 180°. Thus, the desired signal D_{Q}LO_{Q} is in phase with the desired signal D_{I}LO_{I}, and the image signal IM_{Q}LO_{Q} is in opposite phase to the image signal IM_{I}LO_{I}. Therefore, assuming that the conversion gain in the acoustic wave phase shift circuit 22 is B_{SAW}, the desired signal D_{Q}LO_{Q} outputted from the acoustic wave phase shift circuit 22 is expressed as Expression 9, and the image signal IM_{Q}LO_{Q} outputted from the acoustic wave phase shift circuit 22 is expressed as Expression 10.

$${D}_{Q} {LO}_{Q} = {B}_{SAW} \frac{{A}_{RF}}{2} cos {ω}_{IF} t \qquad ( Expression 9 )$$

$${IM}_{Q} {LO}_{Q} = - {B}_{SAW} \frac{{A}_{IM}}{2} cos {ω}_{IF} t \qquad ( Expression 10 )$$

Therefore, when the I signal and the Q signal are combined at the output terminal 210, the image signal IM_{I}LO_{I} and the image signal IM_{Q}LO_{Q}, which are in opposite phase to each other, are reduced or prevented, and the desired signal D_{I}LO_{I} and the desired signal D_{Q}LO_{Q}, which are in phase with each other, are extracted from the output terminal 210. A desired signal D_{OUT} and an image signal IM_{OUT} combined at the output terminal 210 are expressed as Expressions 11 and 12, respectively.

$${D}_{OUT} = {B}_{SAW} {A}_{RF} cos {ω}_{IF} t \qquad ( Expression 11 )$$

$${IM}_{OUT} = 0 \qquad ( Expression 12 )$$

When the phase rotation amount of the acoustic wave phase shift circuit 21 is α° and the phase rotation amount of the acoustic wave phase shift circuit 22 is (α+about 90)°, the desired signal D_{OUT} and the image signal IM_{OUT} combined at the output terminal 210 are expressed as Expressions 13 and 14, respectively.

$${D}_{OUT} = {B}_{SAW} {A}_{RF} cos ( {ω}_{IF} t + α ) \qquad ( Expression 13 )$$

$${IM}_{OUT} = 0 \qquad ( Expression 14 )$$

Table 1 indicates the relationships, for the desired signal D and the image signal IM, between the output signal outputted to the output terminal 210, the phase of the local signal to be multiplied by the quadrature mixer 10, and the phase rotation amount in the acoustic wave device 20. In Table 1, the conversion gain B_{SAW} is set to about 1, and the phase of the local signal LO_{I} and the phase rotation amount of the acoustic wave phase shift circuit 21 are both set to about 0°.

It can be understood from Table 1 that when the phase of the local signal LO_{Q} and the phase rotation amount of the acoustic wave phase shift circuit 22 are both about +90° or about −90°, the desired signal D_{I}LO_{I} and the desired signal D_{Q}LO_{Q} are in phase, and the image signal IM_{I}LO_{I} and the image signal IM_{Q}LO_{Q} are in opposite phase.

Also, it can be understood from Table 1 that when the phase of the local signal LO_{Q} is about +90° and the phase rotation amount of the acoustic wave phase shift circuit 22 is about −90°, and when the phase of the local signal LO_{Q} is about −90° and the phase rotation amount of the acoustic wave phase shift circuit 22 is about +90°, the desired signal D_{I}LO_{I} and the desired signal D_{Q}LO_{Q} are in opposite phase, and the image signal IM_{I}LO_{I} and the image signal IM_{Q}LO_{Q} are in phase.

TABLE 1

| | Signal multiplied | Exponential form of | Trigonometric form of | Output of acoustic wave device 20 | |
|---|---|---|---|---|---|
| Signal | by mixer 10 | output of mixer 10 | output of mixer 10 | Phase rotation +90° | Phase rotation −90* |
| I-path desired signal D_{I} | DI · LO_{I}(+0°) | $\frac{{A}_{RF}}{4} ( {e}^{j {ω}_{IF} t} + {e}^{- j {ω}_{IF} t} )$ | $+ \frac{{A}_{RF}}{2} cos {ω}_{IF} t$ | — | — |
| I-path image signal IM_{I} | IMI · LO_{I}(+0°) | $\frac{{A}_{IM}}{4} ( {e}^{j {ω}_{IF} t} + {e}^{- j {ω}_{IF} t} )$ | $+ \frac{{A}_{IM}}{2} cos {ω}_{IF} t$ | — | — |
| Q-path desired signal D_{Q} | DQ · LO_{Q}(+90°) | $\frac{{A}_{RF}}{4 j} ( {e}^{j {ω}_{IF} t} - {e}^{- j {ω}_{IF} t} )$ | $+ \frac{{A}_{RF}}{2} sin {ω}_{IF} t$ | $+ \frac{{A}_{RF}}{2} cos {ω}_{IF} t$ | $- \frac{{A}_{RF}}{2} cos {ω}_{IF} t$ |
| Q-path image signal IM_{Q} | IMQ · LO_{Q}(+90°) | $- \frac{{A}_{IM}}{4 j} ( {e}^{j {ω}_{IF} t} - {e}^{- j {ω}_{IF} t} )$ | $- \frac{{A}_{IM}}{2} sin {ω}_{IF} t$ | $- \frac{{A}_{IM}}{2} cos {ω}_{IF} t$ | $+ \frac{{A}_{IM}}{2} cos {ω}_{IF} t$ |
| Q-path desired signal D_{Q} | DQ · LO_{Q}(−90°) | $- \frac{{A}_{RF}}{4 j} ( {e}^{j {ω}_{IF} t} - {e}^{- j {ω}_{IF} t} )$ | $- \frac{{A}_{RF}}{2} sin {ω}_{IF} t$ | $- \frac{{A}_{RF}}{2} cos {ω}_{IF} t$ | $+ \frac{{A}_{RF}}{2} cos {ω}_{IF} t$ |
| Q-path image signal IM_{Q} | IMQ · LO_{Q}(−90°) | $\frac{{A}_{IM}}{4 j} ( {e}^{j {ω}_{IF} t} + {e}^{- j {ω}_{IF} t} )$ | $+ \frac{{A}_{IM}}{2} sin {ω}_{IF} t$ | $+ \frac{{A}_{IM}}{2} cos {ω}_{IF} t$ | $- \frac{{A}_{IM}}{2} cos {ω}_{IF} t$ |

Table 2 indicates the conditions under which the desired signals D_{I}LO_{I} and D_{Q}LO_{Q} are in phase and the image signals IM_{I}LO_{I} and IM_{Q}LO_{Q} are in opposite phase at the output terminal 210.

According to Table 2, (1) when the frequency of the desired signal D is F_{LO}+F_{IF}, the frequency of the image signal IM is F_{LO}−F_{IF}, and the phase of the local signal LO_{Q} and the phase rotation amount of the acoustic wave phase shift circuit 22 are both about +90° or about −90°, the desired signal D_{I}LO_{I} and the desired signal D_{Q}LO_{Q} are in phase, and the image signal IM_{I}LO_{I} and the image signal IM_{Q}LO_{Q} are in opposite phase. On the other hand, when the frequency of the desired signal D is F_{LO}−F_{IF} and the frequency of the image signal IM is F_{LO}+F_{IF}, (2) when the phase of the local signal LO_{Q} is about +90° and the phase rotation amount of the acoustic wave phase shift circuit 22 is about −90°, and (3) when the phase of the local signal LO_{Q} is about −90° and the phase rotation amount of the acoustic wave phase shift circuit 22 is about +90°, the desired signal D_{I}LO_{I} and the desired signal D_{Q}LO_{Q} are in phase, and the image signal IM_{I}LO_{I} and the image signal IM_{Q}LO_{Q} are in opposite phase.

In other words, it is understood that the frequency of the desired signal D to be extracted can be changed by changing the frequency F_{LO} of the local signal.

TABLE 2

| | Surface acoustic | | |
|---|---|---|---|
| | wave device | | |
| LO signal phase | phase rotation | Frequency F_{RF} | Frequency F_{IM} |
| difference | amount difference | of desired RF | of image |
| θ_{LOQ} − θ_{LOI} | θ_{SAWQ} − θ_{SAWI} | signal D | signal IM |
| +90° | +90° | F_{LO} + F_{IF} | F_{LO} − F_{IF} |
| +90° | −90° | F_{LO} − F_{IF} | F_{LO} + F_{IF} |
| −90° | +90° | F_{LO} − F_{IF} | F_{LO} + F_{IF} |
| −90° | −90° | F_{LO} + F_{IF} | F_{LO} − F_{IF} |

As indicated in Table 1, when the phase difference between the local signals LO_{Q} and LO_{I} is a predetermined phase difference, ∞ is obtained as the image rejection ratio.

Here, the ratio of the power (P_{D}) of the desired signal D to the power (P_{IM}) of the image signal IM is expressed as Expression 15. Note that δ represents the amplitude error of the local signals LO_{I} and LO_{Q}, and φ represents the phase error of the local signals LO_{I} and LO_{Q}.

$$\frac{{P}_{D}}{{P}_{IM}} = \frac{{A}_{RF}^{2}}{{A}_{IM}^{2}} \cdot \frac{4}{{δ}^{2} + {φ}^{2}} \qquad ( Expression 15 )$$

Since the image rejection ratio IRR is obtained by dividing P_{D}/P_{IM} by A_{RF}²/A_{IM}², which is expressed as Expression 16.

$$IRR = \frac{4}{{δ}^{2} + {φ}^{2}} \qquad ( Expression 16 )$$

When the image rejection ratio IRR is expressed in units of dB, the image rejection ratio IRR is expressed as Expression 17.

$$IRR ( dB ) = 6 - 10 {log}_{10} ( {δ}^{2} + {φ}^{2} ) \qquad ( Expression 17 )$$

In Expression 17, when δ=about 0 and φ=about 1.15°, the IRR is about 40 dB. When δ=about 0 and φ=about 11.42°, the IRR is about 20 dB. When δ=about 0 and φ=about 35.1°, the IRR is about 10 dB.

In the receiver 1 according to the present example embodiment, the required image rejection ratio IRR is, for example, about 10 dB. By securing an image rejection ratio IRR of at least about 10 dB and optimizing the phase rotation amount of the quadrature mixer 10 and the acoustic wave device 20, the reception sensitivity required for the receiver 1 as a mobile communication device can be achieved.

When there is a difference in the conversion gain of the acoustic wave phase shift circuits 21 and 22, the distribution ratio of the I signal and the Q signal may be adjusted by adjusting the amplitude gain by a circuit obtained by combining resistors, inductors, and capacitors, or by adjusting the impedance of the mixers 11 and 12, so that the amplitudes of the image signals IM_{I} and IM_{Q} outputted to the output terminal 210 are sufficiently equalized to satisfy the required image rejection ratio IRR.

In other words, in the receiver 1 according to the present example embodiment, when the phase rotation amount of the I signal in the path P_{I} is α°, the phase rotation amount of the Q signal in the path P_{Q} is β°, and n is an integer, the relationship expressed as Expression 18 or Expression 19 is satisfied.

$$( α + 90 + n \times 360 - 35.1 ) \leq β \leq ( α + 90 + n \times 360 + 35.1 ) \qquad ( Expression 18 )$$

$$( α - 90 + n \times 360 - 35.1 ) \leq β \leq ( α - 90 + n \times 360 + 35.1 ) \qquad ( Expression 19 )$$

Thus, the image signal IM generated by the quadrature mixer 10 can be reduced or prevented by the acoustic wave device 20 at an image rejection ratio of about 10 dB or more. The acoustic wave device 20 for phase conversion is disposed between the output end of the quadrature mixer 10 and the signal output terminal 102. Therefore, a miniaturized mixer-first receiver 1 with low loss can be provided.

More specifically, (1) when the mixer 11 is driven at about 0°, the mixer 12 is driven at about +90°, the phase rotation amount of the acoustic wave phase shift circuit 21 is α°, and the phase rotation amount of the acoustic wave phase shift circuit 22 is (α+about 90)°, the frequency F_{RF} (=F_{LO}+F_{IF}) of the radio-frequency signal can be changed by changing the frequency F_{LO} of the local signal.

(2) When the mixer 11 is driven at about 0°, the mixer 12 is driven at about +90°, the phase rotation amount of the acoustic wave phase shift circuit 21 is α°, and the phase rotation amount of the acoustic wave phase shift circuit 22 is (α−about 90)°, the frequency F_{RF} (=F_{LO}−F_{IF}) of the radio-frequency signal can be changed by changing the frequency F_{LO} of the local signal.

(3) When the mixer 11 is driven at about 0°, the mixer 12 is driven at about −90°, the phase rotation amount of the acoustic wave phase shift circuit 21 is α°, and the phase rotation amount of the acoustic wave phase shift circuit 22 is (α+about 90)°, the frequency F_{RF} (=F_{LO}−F_{IF}) of the radio-frequency signal can be changed by changing the frequency F_{LO} of the local signal.

(4) When the mixer 11 is driven at about 0°, the mixer 12 is driven at about −90°, the phase rotation amount of the acoustic wave phase shift circuit 21 is α°, and the phase rotation amount of the acoustic wave phase shift circuit 22 is (α−about 90)°, the frequency F_{RF} (=F_{LO}+F_{IF}) of the radio-frequency signal can be changed by changing the frequency F_{LO} of the local signal.

The acoustic wave device 20 according to the present example embodiment may also have the characteristics of a band pass filter whose pass band includes the frequency band (frequency F_{IF}) of the desired signal D and whose attenuation band is the other frequency bands than the frequency band of the desired signal D. Thus, in the acoustic wave device 20, compared to polyphase filters and complex filters including resistors and semiconductors, the insertion loss can be reduced, the size can be reduced, the nonlinear distortion can be reduced, steep attenuation characteristics near the pass band can be obtained, and unwanted signals outside the band of the desired signal D can be reduced or prevented.

### 1.4 Circuit Configuration of Acoustic Wave Device 20 According to Example 1

Next, an example of the circuit configuration of an acoustic wave device 20 according to Example 1 of an example embodiment of the present invention is described.

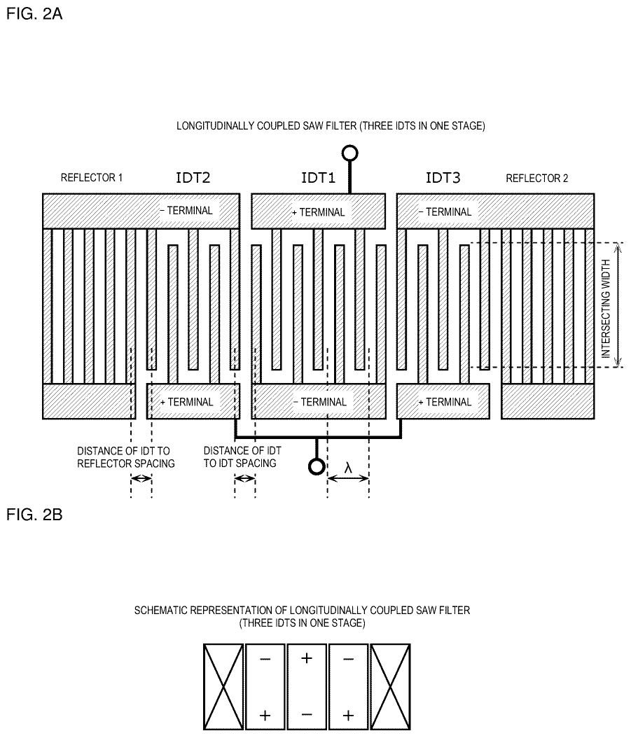

FIG. 2A is a diagram showing an example of an electrode configuration of a longitudinally coupled SAW filter. FIG. 2B is a diagram showing a schematic representation of the longitudinally coupled SAW filter. As shown in FIG. 2A, the longitudinally coupled SAW filter includes a plurality of IDT electrodes and two reflectors disposed on both sides of the plurality of IDT electrodes. By adjusting the number of pairs of the IDT electrodes, the spacing between the IDT electrodes, and the spacing between the IDT electrodes and the reflectors, the longitudinally coupled SAW filter has a filter function that is achieved by exciting a resonant mode in which two or more surface acoustic waves resonate. Further, the longitudinally coupled SAW filter can rotate the phase of a radio-frequency signal by adjusting the spacing between the IDT electrodes and the reflectors, the IDT electrode configuration, and the connection configuration between the IDT electrodes. By using a longitudinally coupled SAW filter as the acoustic wave device 20, the acoustic wave device 20 can achieve both the phase rotation function and the filter function with low loss and steep attenuation characteristics.

In the following description, when describing the configuration of the acoustic wave device 20 including a longitudinally coupled SAW filter, the electrode configuration shown in FIG. 2A will be described using the schematic representation shown in FIG. 2B.

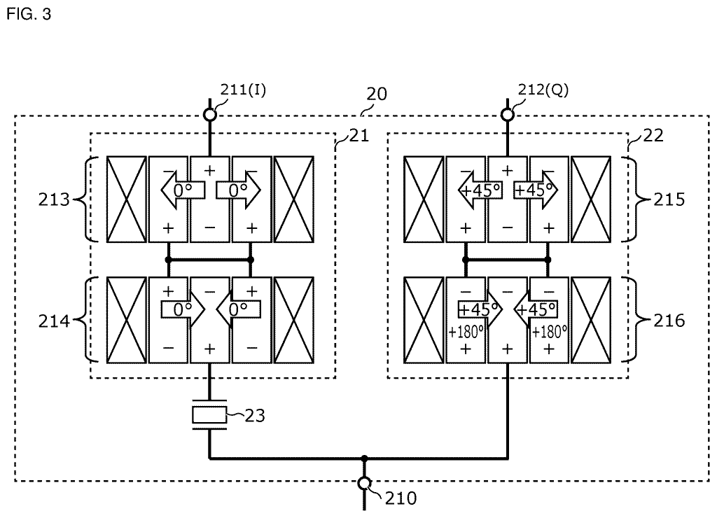

FIG. 3 is a circuit configuration diagram of the acoustic wave device 20 according to Example 1. The acoustic wave device 20 according to the present example includes acoustic wave phase shift circuits 21 and 22, a phase compensator 23, a non-differential input I-terminal 211, a non-differential input Q-terminal 212, and a non-differential output terminal 210.

The acoustic wave phase shift circuit 21 include a longitudinally coupled SAW filter 213 including three IDT electrodes and two reflectors disposed on a piezoelectric substrate, and a longitudinally coupled SAW filter 214 including three IDT electrodes and two reflectors disposed on the substrate. The acoustic wave phase shift circuit 22 includes a longitudinally coupled SAW filter 215 including three IDT electrodes and two reflectors disposed on a piezoelectric substrate, and a longitudinally coupled SAW filter 216 including three IDT electrodes and two reflectors disposed on the substrate.

The +terminal of the center IDT electrode of the SAW filter 213 is connected to the input I-terminal 211, and the +terminals of the left and right IDT electrodes of the SAW filter 213 are connected to the +terminals of the left and right IDT electrodes of the SAW filter 214. The +terminal of the center IDT electrode of the SAW filter 214 is connected to the output terminal 210 with the phase compensator 23 connected therebetween. The −terminals of the SAW filters 213 and 214 are grounded.

The +terminal of the center IDT electrode of the SAW filter 215 is connected to the input Q-terminal 212, and the +terminals of the left and right IDT electrodes of the SAW filter 215 are connected to the −terminals of the left and right IDT electrodes of the SAW filter 216. The +terminal of the center IDT electrode of the SAW filter 216 is connected to the output terminal 210. The −terminal of the SAW filter 215, the −terminal of the center IDT electrode of the SAW filter 216, and the +terminals of the left and right IDT electrodes of the SAW filter 216 are grounded.

With the configuration described above, in the acoustic wave phase shift circuit 21, there is no phase rotation between the IDT electrodes of the SAW filters 213 and 214. On the other hand, in the acoustic wave phase shift circuit 22, the phase is rotated by about 45° between the center IDT electrode and the left and right IDT electrodes of the SAW filter 215, and the phase is rotated by about 45° between the left and right IDT electrodes and the center IDT electrode of the SAW filter 216. This is because the spacing between the center IDT electrode and the left and right IDT electrodes in the SAW filters 215 and 216 is made different from the corresponding spacing in the SAW filters 213 and 214. Alternatively, the spacing between the left and right IDT electrodes and the reflectors in the SAW filters 215 and 216 may be made different from the spacing between the left and right IDT electrodes and the reflectors in the SAW filters 213 and 214. Further, the phase is rotated by about 180° between the SAW filter 215 and the SAW filter 216. This is because the +terminals of the left and right IDT electrodes of the SAW filter 215 are connected to the −terminals of the left and right IDT electrodes of the SAW filter 216.

In other words, the phase rotation amount of the I signal transmitted from the input I-terminal 211 to the output terminal 210 is about 0°, and the phase rotation amount of the Q signal transmitted from the input Q-terminal 212 to the output terminal 210 is about −90°.

With the configuration described above, when a plurality of SAW filters are cascade-connected, steeper attenuation characteristics and higher attenuation can be obtained compared with a single SAW filter. Further, by reducing (the absolute value of) the phase rotation amount per SAW filter stage to less than about 90°, the acoustic wave phase shift circuit 21 or 22, as a total, can perform a phase rotation of about 90°, so that it becomes easy to match the amplitude characteristics of the I signal and the Q signal.

Further, by reversing the polarities of the IDT electrodes of the SAW filter or shifting the spacing between the IDT electrodes by about ½ wavelength, the phase of the acoustic wave phase shift circuit 22 can be inverted by about 180°. With such a configuration, the relationship between the I signal and the Q signal outputted to the output terminal 210, and the relationship between the desired signal D and the image signal IM can be arbitrarily set with respect to the phase of the local signal to be multiplied by the quadrature mixer 10 and the phase rotation amount in the acoustic wave device 20.

The phase rotation amount of the acoustic wave phase shift circuits 21 and 22 may be adjusted using a (narrow-period electrode finger) method in which, in a given IDT electrode, the spacing of the electrode finger close to the adjacent IDT electrode or the spacing of the electrode finger close to a reflector is smaller than the spacing between the electrode fingers of the given IDT electrode.

By using a longitudinally coupled SAW filter as the acoustic wave phase shift circuits 21 and 22, band pass characteristics with low loss and steep attenuation characteristics can be obtained as compared with a surface acoustic wave phase shifter based on a transversal surface acoustic wave phase shifter having a wide pass band and including unidirectional IDT electrodes.

The phase compensator 23 is, for example, a SAW resonator in the present example and is connected between the acoustic wave phase shift circuit 21 and the output terminal 210. More specifically, the phase compensator 23 is disposed in series in a path connecting the acoustic wave phase shift circuit 21 and the output terminal 210. Thus, the phase compensator 23 can compensate the phase of the I signal that has passed through the acoustic wave phase shift circuit 21. By using the phase compensator 23 as a SAW resonator, the phase compensator 23 can be added in the same process on the same substrate as each SAW filter.

As in the present example, when the phase compensator 23 (SAW resonator) is disposed in series with the above-described path, it is possible to shift the phase of the high-frequency side of the pass band of the acoustic wave phase shift circuit 21 and increase the attenuation and steepness of the bands farther on the high-frequency side than the pass band. When the phase compensator 23 (SAW resonator) is connected between the above-described path and the ground, it is possible to shift the phase of the low-frequency side of the pass band of the acoustic wave phase shift circuit 21 and increase the attenuation and steepness of the bands farther on the low-frequency side than the pass band.

When the I signal and the Q signal are respectively phase-adjusted by the acoustic wave phase shift circuits 21 and 22 and combined at the output terminal 210, it is required that the phase difference between the I signal and the Q signal is uniform over the frequency band of the I signal and the Q signal. However, in the case of an acoustic wave device to which the phase compensator 23 is not added, when the I signal and the Q signal have a wide frequency band, it is not easy to obtain a predetermined phase difference relationship between the I signal and the Q signal with high accuracy over such a frequency band.

On the other hand, with the acoustic wave device 20 according to the present example, since the acoustic wave phase shift circuits 21 and 22 are used as the circuit to perform phase conversion and balance/non-balance conversion, the circuit to perform phase conversion of the I signal and the Q signal can be miniaturized with low loss. Further, since the phase compensator 23 is added between the input I-terminal 211 and the input Q-terminal 212 and the output terminal 210, the phase difference between the I signal and the Q signal at the output terminal 210 can be made uniform over the pass band of the acoustic wave phase shift circuits 21 and 22, and the image component included in the IQ signal can be reduced or prevented with high accuracy. Thus, a miniaturized acoustic wave device 20 capable of transmitting radio-frequency signals with low loss and low noise can be provided.

### 1.5 Circuit Configuration of Receiver 1A According to Modification 1

Next, the circuit configuration of a receiver 1A according to Modification 1 of an example embodiment of the present invention will be described.

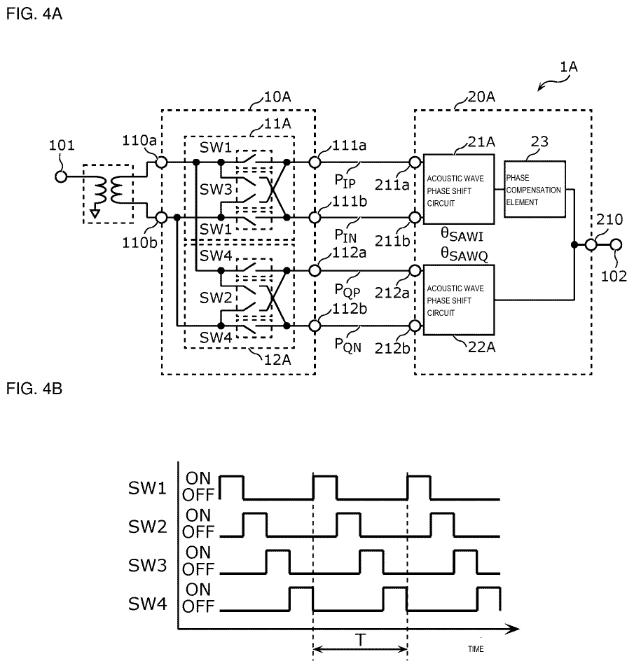

FIG. 4A is a circuit configuration diagram of the receiver 1A according to Modification 1. FIG. 4B is a timing chart showing driving signals of a quadrature mixer 10A according to Modification 1. As shown in FIG. 4A, the receiver 1A includes the quadrature mixer 10A, an acoustic wave device 20A, an antenna connection terminal 101, and a signal output terminal 102.

The receiver 1A may include, for example, a balun connected between the antenna connection terminal 101 and the quadrature mixer 10A.

The quadrature mixer 10A includes mixer circuits 11A and 12A, an input terminal 110a (first differential input terminal) and an input terminal 110b (second differential input terminal), an output I-terminal 111a (first differential output I-terminal) and an output I-terminal 111b (second differential output I-terminal), an output Q-terminal 112a (first differential output Q-terminal) and an output Q-terminal 112b (second differential output Q-terminal). A Gilbert cell mixer, for example, which is a double balanced mixer, is provided as the quadrature mixer 10A.

The mixer circuit 11A is an example of the first mixer and is connected between the input terminals 110a and 110b and the output I-terminals 111a and 111b. The mixer circuit 11A performs frequency conversion to convert radio-frequency differential signals in opposite phase to each other inputted from the input terminals 110a and 110b into an I_{P} signal and an I_{N} signal in opposite phase to each other, and outputs the I_{P} signal and the I_{N} signal from the output I-terminals 111a and 111b, respectively. The mixer circuit 12A is an example of the second mixer and is connected between the input terminals 110a and 110b and the output Q-terminals 112a and 112b. The mixer circuit 12A performs frequency conversion to convert the radio-frequency differential signals in opposite phase to each other inputted from the input terminals 110a and 110b into a Q_{P} signal and a Q_{N} signal in opposite phase to each other and having a phase difference of about 90° from the I_{P} signal and the I_{N} signal, and outputs the Q_{P} signal and the Q_{N} signal from the output Q-terminals 112a and 112b, respectively.

The mixer circuit 11A includes switches SW1 and SW3, and the mixer circuit 12A includes switches SW2 and SW4. The switch SW1 includes its first end connected to the input terminal 110a, its second end connected to the input terminal 110b, its third end connected to the output I-terminal 111a, and its fourth end connected to the output I-terminal 111b. The switch SW1 synchronously switches the connection and disconnection between the first end and the third end, and the connection and disconnection between the second end and the fourth end. The switch SW3 includes its first end connected to the input terminal 110a, its second end connected to the input terminal 110b, its third end connected to the output I-terminal 111b, and its fourth end connected to the output I-terminal 111a. The switch SW3 synchronously switches the connection and disconnection between the first end and the third end, and the connection and disconnection between the second end and the fourth end. The switch SW2 includes its first end connected to the input terminal 110a, its second end connected to the input terminal 110b, its third end connected to the output Q-terminal 112b, and its fourth end connected to the output Q-terminal 112a. The switch SW2 synchronously switches the connection and disconnection between the first end and the third end, and the connection and disconnection between the second end and the fourth end. The switch SW4 includes its first end connected to the input terminal 110a, its second end connected to the input terminal 110b, its third end connected to the output Q-terminal 112a, and its fourth end connected to the output Q-terminal 112b. The switch SW4 synchronously switches the connection and disconnection between the first end and the third end, and the connection and disconnection between the second end and the fourth end.

As shown in FIG. 4B, the switch SW1 is driven by a local signal with a phase of about 0°, the switch SW2 is driven by a local signal with a phase of about −90°, the switch SW3 is driven by a local signal with a phase of about 180°, and the switch SW4 is driven by a local signal with a phase of about 90° (about −270°). If the period of each local signal is T, then the on-period of each switch is about T/4.

As shown in FIG. 4A, the acoustic wave device 20A includes acoustic wave phase shift circuits 21A and 22A, an input I-terminal 211a (I_{P} signal terminal), an input I-terminal 211b (I_{N} signal terminal), an input Q-terminal 212a (Q_{P} signal terminal), an input Q-terminal 212b (Q_{N} signal terminal), and an output terminal 210. The input I-terminal 211a is connected to the output I-terminal 111a, the input I-terminal 211b is connected to the output I-terminal 111b, the input Q-terminal 212a is connected to the output Q-terminal 112a, and the input Q-terminal 212b is connected to the output Q-terminal 112b.

The acoustic wave phase shift circuit 21A phase-adjusts the I_{P} signal transmitted through a path P_{IP} connecting the mixer circuit 11A and the acoustic wave phase shift circuit 21A, and phase-adjusts the I_{N} signal transmitted through a path P_{IN} connecting the mixer circuit 11A and the acoustic wave phase shift circuit 21A. The acoustic wave phase shift circuit 21A defines a filter circuit whose pass band includes the frequencies of the I_{P} signal and the I_{N} signal.

The acoustic wave phase shift circuit 22A phase-adjusts the Q_{P} signal transmitted through a path P_{QP} connecting the mixer circuit 12A and the acoustic wave phase shift circuit 22A, and phase-adjusts the Q_{N} signal transmitted through a path P_{QN} connecting the mixer circuit 12A and the acoustic wave phase shift circuit 22A. The acoustic wave phase shift circuit 22A defines a filter circuit whose pass band includes the frequencies of the Q_{P} signal and the Q_{N} signal.

The phase compensator 23 is connected between the acoustic wave phase shift circuit 21A and the output terminal 210, and compensates the phase of the I signal that has passed through the acoustic wave phase shift circuit 21A. The phase compensator 23 is, for example, an acoustic wave resonator. When the acoustic wave phase shift circuits 21A and 22A each include a SAW resonator, it is preferable that the phase compensator 23 is also a SAW resonator.

The phase compensator 23 may be connected to at least one of (1) between the input I-terminal 211a and the acoustic wave phase shift circuit 21A, (2) between the input I-terminal 211b and the acoustic wave phase shift circuit 21A, (3) between the input Q-terminal 212a and the acoustic wave phase shift circuit 22A, (4) between the input Q-terminal 212b and the acoustic wave phase shift circuit 22A, (5) between the output terminal 210 and the acoustic wave phase shift circuit 21A, and (6) between the output terminal 210 and the acoustic wave phase shift circuit 22A.

Further, since each of the I signal terminal and the Q signal terminal is a differential terminal, as in the receiver 1A according to the present modification, it is possible to directly connect a double balanced quadrature mixer using, for example, a Gilbert cell mixer or the like and the acoustic wave device 20A without connecting a differential/non-differential conversion element with a large size therebetween. The Gilbert cell mixer has excellent noise characteristics, and is easy to implement in a CMOS (complementary metal oxide semiconductor) circuit. The differential/non-differential conversion element is defined by a transformer including a coil of large size. Therefore, it is possible to provide a low-noise, miniaturized acoustic wave device 20A with a simplified configuration on the input side.

Since the output terminal 210 is a non-differential terminal, it is not necessary to include a differential/non-differential conversion element separately. Further, since the number of connections to semiconductor devices, such as, for example, amplifiers, connected to the output terminal 210 can be reduced, it is possible to provide a miniaturized acoustic wave device 20A with a simplified configuration on the output side.

### 1.6 Operating Principle of Receiver 1A

Here, the operating principle of the receiver 1A according to Modification 1 will be described below.

The receiver 1A performs frequency conversion processing and phase conversion processing on radio-frequency differential signals having frequency F_{RF} and in opposite phase to each other, and outputs the result to the low-noise amplifier 2 and the RFIC 3 with low loss.

A radio-frequency signal including a desired signal D_{P} and an image signal IM_{P} is inputted to the input terminal 110a, a radio-frequency signal including a desired signal D_{N} and an image signal IM_{N} is inputted to the input terminal 110b, and the radio-frequency signals are distributed to the mixer circuits 11A and 12A. At this time, desired signals D_{IP} and D_{IN} and image signals IM_{IP} and IM_{IN} inputted to the mixer circuit 11A are modulated to frequencies (−F_{IF}) and (+F_{IF}), so that the desired signal D_{IP} and the image signal IM_{IP} are in phase, and the desired signal D_{IN} and the image signal IM_{IN} are in phase. On the other hand, a desired signal D_{QP} and an image signal IM_{QP} inputted to the mixer circuit 12A are modulated to frequencies (−F_{IF}) and (+F_{IF}), the desired signal D_{QP} is rotated by about 90° (or about −90°) with respect to the desired signal D_{IP}, a desired signal D_{QN} is rotated by about 90° (or about −90°) with respect to the desired signal D_{IN}, the image signal IM_{QP} is rotated by about −90° (or about 90°) with respect to the image signal IM_{IP}, and an image signal IM_{QN} is rotated by about −90° (or about 90°) with respect to the image signal IM_{IN}.

Tables 3 and 4 indicate the relationships, for the desired signal D and the image signal IM, between the output signal outputted to the output terminal 210, the phase of the local signal to be multiplied by the quadrature mixer 10A, and the phase rotation amount in the acoustic wave device 20A (the phase rotation amount of the acoustic wave phase shift circuit).

TABLE 3

| | | Local signal | | Output of mixer | Output phase |
|---|---|---|---|---|---|
| Signal | Input of mixer 10A | (phase) | Terminal | 104 | of mixer 10A |
| Desired signal D | $+ \frac{{A}_{RF}}{4} ( \text{?} + \text{?} )$ | $\frac{\text{?} + \text{?}}{2} ( 0 )$ | I+ | $+ \frac{{A}_{RF}}{8} ( \text{?} + \text{?} )$ | 0 |
| | $- \frac{{A}_{RF}}{4} ( \text{?} + \text{?} )$ | $\frac{\text{?} + \text{?}}{2} ( 0 )$ | I− | $- \frac{{A}_{RF}}{8} ( \text{?} + \text{?} )$ | 0 |
| | $+ \frac{{A}_{RF}}{4} ( \text{?} + \text{?} )$ | | Q+ | $+ \frac{{A}_{RF}}{8} ( \text{?} - \text{?} )$ | $- \frac{π}{2}$ |
| | $- \frac{{A}_{RF}}{4} ( \text{?} + \text{?} )$ | | Q− | $- \frac{{A}_{RF}}{8} ( \text{?} - \text{?} )$ | $+ \frac{π}{2}$ |
| Image signal IM | $+ \frac{{A}_{IM}}{4} ( \text{?} + \text{?} )$ | $\frac{\text{?} + \text{?}}{2} ( 0 )$ | I+ | $+ \frac{{A}_{IM}}{8} ( \text{?} + \text{?} )$ | 0 |
| | $- \frac{{A}_{IM}}{4} ( \text{?} + \text{?} )$ | $\frac{- \text{?} + \text{?}}{2 j} ( π / 2 )$ | I− | $- \frac{{A}_{IM}}{8} ( \text{?} + \text{?} )$ | 0 |
| | $+ \frac{{A}_{IM}}{4} ( \text{?} + \text{?} )$ | | Q+ | $- \frac{{A}_{IM}}{8} ( \text{?} - \text{?} )$ | $+ \frac{π}{2}$ |
| | $- \frac{{A}_{IM}}{4} ( \text{?} + \text{?} )$ | | Q− | $+ \frac{{A}_{IM}}{8} ( \text{?} - \text{?} )$ | $- \frac{π}{2}$ |
| | | | Phase rotation amount | Output of acoustic | |
| | | | of acoustic wave | wave phase shift | Output of acoustic |
| | | Signal | phase shift circuit | circait | wave device 20A |
| | | Desired signal D | 0 | $+ {B}_{SAW} \frac{{A}_{RF}}{8} ( \text{?} + \text{?} )$ | $+ {B}_{SAW} \frac{{A}_{RF}}{2} ( \text{?} + \text{?}$ |
| | | | π | $+ {B}_{SAW} \frac{{A}_{RF}}{8} ( \text{?} + \text{?} )$ | |
| | | | $+ \frac{π}{2}$ | $+ {B}_{SAW} \frac{{A}_{RF}}{8} ( \text{?} + \text{?} )$ | |
| | | | $- \frac{π}{2}$ | $+ {B}_{SAW} \frac{{A}_{RF}}{8} ( \text{?} + \text{?} )$ | |
| | | Image signal IM | 0 | $+ {B}_{SAW} \frac{{A}_{IM}}{8} ( \text{?} + \text{?} )$ | 0 |
| | | | π | $+ {B}_{SAW} \frac{{A}_{IM}}{8} ( \text{?} + \text{?} )$ | |
| | | | $+ \frac{π}{2}$ | $- {B}_{SAW} \frac{{A}_{IM}}{8} ( \text{?} + \text{?} )$ | |
| | | | $- \frac{π}{2}$ | $- {B}_{SAW} \frac{{A}_{IM}}{8} ( \text{?} + \text{?} )$ | |

F_{RF} = F_{LO} + F_{IF}, θ_{LOI} = 0°, θ_{LOQ} = +90°, mixer differential output, acoustic wave device differential input/non-differential output
$\text{?} \text{indicates text missing or illegible when filed}$

Table 3 indicates the conditions under which the desired signals D_{I}LO_{I} and D_{Q}LO_{Q} are in phase and the image signals IM_{I}LO_{I} and IM_{Q}LO_{Q} are in opposite phase at the output terminal 210, when the frequency of the desired signal D is F_{LO}+F_{IF} and the frequency of the image signal IM is F_{LO}−F_{IF}. In Table 3, when the phase rotation amount of the phase of the local signal LO_{Q} with respect to the local signal LO_{I} is about +90°, the phase rotation amount of the desired signal D_{QP} with respect to the desired signal D_{IP} is rotated by about +90°, and the phase rotation amount of the desired signal D_{QN} with respect to the desired signal D_{IN} is rotated by about −90° in the acoustic wave phase shift circuit 22A. Also, when the phase rotation amount of the phase of the local signal LO_{Q} with respect to the local signal LO_{I} is about −90°, the phase rotation amount of the desired signal D_{QP} with respect to the desired signal D_{IP} is rotated by about −90°, and the phase rotation amount of the desired signal D_{QN} with respect to the desired signal D_{IN} is rotated by about +90° in the acoustic wave phase shift circuit 22A.

TABLE 4

| | Input of | Local signal | | Output of mixer | Output phase |
|---|---|---|---|---|---|
| Signal | mixer 10A | (phase) | Terminal | 104 | of mixer 10A |
| Desired signal D | $+ \frac{{A}_{RF}}{4} ( \text{?} + \text{?} )$ | $\frac{\text{?} + \text{?}}{2} ( 0 )$ | I+ | $+ \frac{{A}_{RF}}{8} ( \text{?} + \text{?} )$ | 0 |
| | $- \frac{{A}_{RF}}{4} ( \text{?} + \text{?} )$ | $\frac{- \text{?} + \text{?}}{2 j} ( π / 2 )$ | I− | $- \frac{{A}_{RF}}{8} ( \text{?} + \text{?} )$ | 0 |
| | $+ \frac{{A}_{RF}}{4} ( \text{?} + \text{?} )$ | | Q+ | $+ \frac{{A}_{RF}}{8 j} ( \text{?} - \text{?} )$ | $+ \frac{π}{2}$ |
| | $- \frac{{A}_{RF}}{4} ( \text{?} + \text{?} )$ | | Q− | $- \frac{{A}_{RF}}{8 j} ( \text{?} - \text{?} )$ | $- \frac{π}{2}$ |
| Image signal IM | $+ \frac{{A}_{IM}}{4} ( \text{?} + \text{?} )$ | $\frac{\text{?} + \text{?}}{2} ( 0 )$ | I+ | $+ \frac{{A}_{IM}}{8} ( \text{?} + \text{?} )$ | 0 |
| | $- \frac{{A}_{IM}}{4} ( \text{?} + \text{?} )$ | $\frac{- \text{?} + \text{?}}{2 j} ( π / 2 )$ | I− | $- \frac{{A}_{IM}}{8} ( \text{?} + \text{?} )$ | 0 |
| | $+ \frac{{A}_{IM}}{4} ( \text{?} + \text{?} )$ | | Q+ | $- \frac{{A}_{IM}}{8 j} ( \text{?} - \text{?} )$ | $- \frac{π}{2}$ |
| | $- \frac{{A}_{IM}}{4} ( \text{?} + \text{?} )$ | | Q− | $+ \frac{{A}_{IM}}{8 j} ( \text{?} - \text{?} )$ | $+ \frac{π}{2}$ |
| | | | Phase rotation amount | Output of acoustic | |
| | | | of acoustic wave | wave phase shift | Output of acoustic |
| | | Signal | phase shift circuit | circait | wave device 20A |
| | | Desired signal D | 0 | $+ {B}_{SAW} \frac{{A}_{RF}}{8} ( \text{?} + \text{?} )$ | $+ {B}_{SAW} \frac{{A}_{RF}}{2} ( \text{?} + \text{?} )$ |
| | | | π | $+ {B}_{SAW} \frac{{A}_{RF}}{8} ( \text{?} + \text{?} )$ | |
| | | | $- \frac{π}{2}$ | $+ {B}_{SAW} \frac{{A}_{RF}}{8} ( \text{?} + \text{?} )$ | |
| | | | $+ \frac{π}{2}$ | $+ {B}_{SAW} \frac{{A}_{RF}}{8} ( \text{?} + \text{?} )$ | |
| | | Image signal IM | 0 | $+ {B}_{SAW} \frac{{A}_{IM}}{8} ( \text{?} + \text{?} )$ | 0 |
| | | | π | $+ {B}_{SAW} \frac{{A}_{IM}}{8} ( \text{?} + \text{?} )$ | |
| | | | $- \frac{π}{2}$ | $- {B}_{SAW} \frac{{A}_{IM}}{8} ( \text{?} + \text{?} )$ | |
| | | | $+ \frac{π}{2}$ | $- {B}_{SAW} \frac{{A}_{IM}}{8} ( \text{?} + \text{?} )$ | |

F_{RF} = F_{LO} + F_{IF}, θ_{LOI} = 0°, θ_{LOQ} = +90°, mixer differential output, acoustic wave device differential input/non-differential output
$\text{?} \text{indicates text missing or illegible when filed}$

Table 4 indicates the conditions under which the desired signals D_{I}LO_{I} and D_{Q}LO_{Q} are in phase and the image signals IM_{I}LO_{I} and IM_{Q}LO_{Q} are in opposite phase at the output terminal 210, when the frequency of the desired signal D is F_{LO}−F_{IF} and the frequency of the image signal IM is F_{LO}+F_{IF}. In Table 4, when the phase rotation amount of the phase of the local signal LO_{Q} with respect to the local signal LO_{I} is about +90°, the phase rotation amount of the desired signal D_{QP} with respect to the desired signal D_{IP} is rotated by about −90° and the phase rotation amount of the desired signal D_{QN} with respect to the desired signal D_{IN} is rotated by about +90° in the acoustic wave phase shift circuit 22A. Also, when the phase rotation amount of the phase of the local signal LO_{Q} with respect to the local signal LO_{I} is about −90°, the phase rotation amount of the desired signal D_{QP} with respect to the desired signal D_{IP} is rotated by about +90° and the phase rotation amount of the desired signal D_{QN} with respect to the desired signal D_{IN} is rotated by about −90° in the acoustic wave phase shift circuit 22A.

As indicated in Tables 3 and 4, when the phase difference between the local signals LO_{Q} and LO_{I} is a predetermined phase difference, ∞ is obtained as the image rejection ratio. Here, in the receiver 1A according to the present modification, as in the receiver 1 according to the above-described example embodiment, the required image rejection ratio IRR is, for example, about 10 dB.

At this time, in the receiver 1A according to the present modification, when the frequency of the desired signal D is F_{LO}+F_{IF} and the frequency of the image signal IM is F_{LO}−F_{IF}, the phase rotation amount of the I signal transmitted from the input I-terminal 211a and the input I-terminal 211b to the output terminal 210 is α°. Further, for example, the phase rotation amount of the I_{P} signal transmitted from the input I-terminal 211a to the output terminal 210 is equal to or greater than (α+n×360−35.1)° and equal to or less than (α+n×360+35.1)°, and the phase rotation amount of the I_{N} signal transmitted from the input I-terminal 211b to the output terminal 210 is equal to or greater than (α+180+n×360−35.1)° and equal to or less than (α+180+n×360+35.1)°. At this time, when the value obtained by subtracting the phase of the local signal that drives the mixer circuit 11A from the phase of the local signal that drives the mixer circuit 12A is (+90+n×360)°, and the phase rotation amount of the Q_{P} signal transmitted from the input Q-terminal 212a to the output terminal 210 is β1° and the phase rotation amount of the Q_{N} signal transmitted from the input Q-terminal 212b to the output terminal 210 is β2°, the relationship expressed as Expression 20 is satisfied.

$$( α + 90 + n \times 360 - 35.1 ) \leq β 1 \leq ( α + 90 + n \times 360 + 35.1 ) \qquad ( Expression 20 )$$

$$( α - 90 + n \times 360 - 35.1 ) \leq β 2 \leq ( α - 90 + n \times 360 + 35.1 )$$

When the value obtained by subtracting the phase of the local signal that drives the mixer circuit 11A from the phase of the local signal that drives the mixer circuit 12A is (−90+n×360)°, the relationship expressed as Expression 21 is satisfied.

$$( α - 90 + n \times 360 - 35.1 ) \leq β 1 \leq ( α - 90 + n \times 360 + 35.1 ) \qquad ( Expression 21 )$$

$$( α + 90 + n \times 360 - 35.1 ) \leq β2 \leq ( α + 90 + n \times 360 + 35.1 )$$

Thus, the image signal IM generated by the quadrature mixer 10A can be reduced or prevented by the acoustic wave device 20A at an image rejection ratio of about 10 dB or more. Further, instead of providing circuit elements such as baluns and transformers, the acoustic wave device 20A for phase adjustment is provided between the output end of the quadrature mixer 10A and the signal output terminal 102. Therefore, it is possible to provide a miniaturized mixer-first receiver 1A with low loss.

Further, the frequency F_{RF} (=F_{LO}+F_{IF}) of the radio-frequency signal can be changed by changing the frequency F_{LO} of the local signal. Further, a quadrature mixer 10A including a double balanced mixer with excellent performance can be used as a semiconductor circuit.

Further, in the receiver 1A according to the present modification, when the frequency of the desired signal D is F_{LO}−F_{IF} and the frequency of the image signal IM is F_{LO}+F_{IF}, the phase rotation amount of the I signal transmitted from the input I-terminal 211a and the input I-terminal 211b to the output terminal 210 is α°. Further, for example, the phase rotation amount of the I_{P} signal transmitted from the input I-terminal 211a to the output terminal 210 is equal to or greater than (α+n×360−35.1)° and equal to or less than (α+n×360+35.1)°, and the phase rotation amount of the I_{N} signal transmitted from the input I-terminal 211b to the output terminal 210 is equal to or greater than (α+180+n×360−35.1)° and equal to or less than (α+180+n×360+35.1)°. At this time, when the value obtained by subtracting the phase of the local signal that drives the mixer circuit 11A from the phase of the local signal that drives the mixer circuit 12A is (+90+n×360)°, and the phase rotation amount of the Q_{P} signal transmitted from the input Q-terminal 212a to the output terminal 210 is β1° and the phase rotation amount of the Q_{N} signal transmitted from the input Q-terminal 212b to the output terminal 210 is β2°, the relationship expressed as Expression 21 is satisfied.

Also, when the value obtained by subtracting the phase of the local signal that drives the mixer circuit 11A from the phase of the local signal that drives the mixer circuit 12A is (−90+n×360)°, the relationship expressed as Expression 20 is satisfied.

Thus, the frequency F_{RF} (=F_{LO}−F_{IF}) of the radio-frequency signal can be changed by changing the frequency F_{LO} of the local signal.

### 1.7 Circuit Configuration of Acoustic Wave Device 20A According to Modification 1

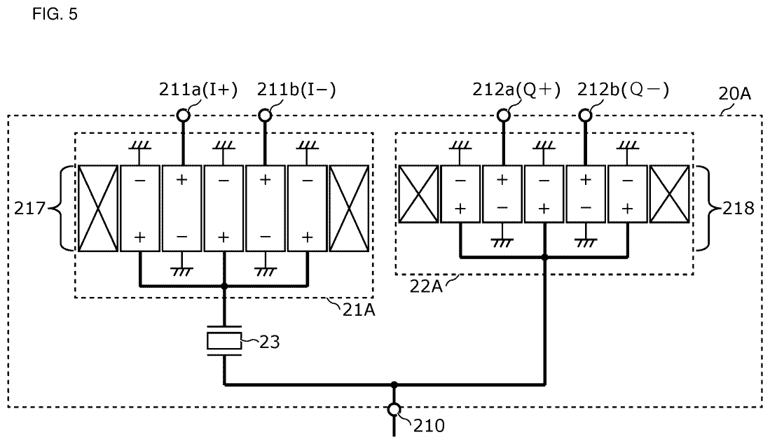

FIG. 5 is a circuit configuration diagram of an acoustic wave device 20A according to Modification 1. The acoustic wave device 20A according to the present modification includes acoustic wave phase shift circuits 21A and 22A, a phase compensator 23, differential input I-terminals 211a and 211b, differential input Q-terminals 212a and 212b, and a non-differential output terminal 210.

The acoustic wave phase shift circuit 21A includes a longitudinally coupled SAW filter 217 including five IDT electrodes (referred to as a first IDT electrode, a second IDT electrode, a third IDT electrode, a fourth IDT electrode, and a fifth IDT electrode in an order from the left side in FIG. 5) and two reflectors disposed on a piezoelectric substrate. The acoustic wave phase shift circuit 22A includes a longitudinally coupled SAW filter 218 includes five IDT electrodes (referred to as a first IDT electrode, a second IDT electrode, a third IDT electrode, a fourth IDT electrode, and a fifth IDT electrode in an order from the left side in FIG. 5) and two reflectors disposed on a piezoelectric substrate.

The +terminal of the second IDT electrode of the SAW filter 217 is connected to the input I-terminal 211a, the +terminal of the fourth IDT electrode of the SAW filter 217 is connected to the input I-terminal 211b, and the +terminals of the first IDT electrode, the third IDT electrode, and the fifth IDT electrode of the SAW filter 217 are connected to the output terminal 210 with the phase compensator 23 connected therebetween. The +terminal of the second IDT electrode of the SAW filter 218 is connected to the input Q-terminal 212a, the +terminal of the fourth IDT electrode of the SAW filter 218 is connected to the input Q-terminal 212b, and the +terminals of the first IDT electrode, the third IDT electrode, and the fifth IDT electrode of the SAW filter 218 are connected to the output terminal 210. The −terminals of the SAW filters 217 and 218 are grounded.

In the above-described configuration of the acoustic wave device 20A, since the phase difference between the I signal at the input I-terminal (input I-terminals 211a and 211b) and the Q signal at the input Q-terminal (input Q-terminals 212a and 212b) is about 90°, the phase difference between the pass bands of the acoustic wave phase shift circuits 21A and 22A is designed to be about −90°.

Table 5 indicates the electrode parameters of the SAW filters 217 and 218, and the phase compensator 23 of the acoustic wave device 20A according to Modification 1.

TABLE 5

| | | First IDT | Second IDT | Third IDT | Fourth IDT | Fifth IDT |
|---|---|---|---|---|---|---|
| | | electrode | electrode | electrode | electrode | electrode |
| Acoustic wave | Number of | 33 | 56 | 35 | 56 | 33 |
| phase shift | electrode | | | | | |
| circuit 21A | fingers | | | | | |
| | Wavelength | 2.554 | 2.510 | 2.578 | 2.510 | 2.554 |
| | of electrode | | | | | |
| | finger (μm) | | | | | |
| | Duty | 0.65 | | | | |
| | Intersecting | 45 | | | | |
| | width (μm) | | | | | |
| Acoustic wave | Number of | 35 | 62 | 35 | 62 | 35 |
| phase shift | electrode | | | | | |
| circuit 22A | fingers | | | | | |
| | Wavelength | 2.511 | 2.513 | 2.508 | 2.513 | 2.511 |
| | of electrode | | | | | |
| | finger (μm) | | | | | |
| | Duty | 0.65 | | | | |
| | Intersecting | 40 | | | | |
| | width (μm) | | | | | |
| Phase | Number of | 111 | | | | |
| compensator | electrode | | | | | |
| 23 | fingers | | | | | |
| | Wavelength | 2.476 | | | | |
| | of electrode | | | | | |
| | finger (μm) | | | | | |
| | Duty | 0.60 | | | | |
| | Intersecting | 50 | | | | |
| | width (μm) | | | | | |

The method of making the phase difference between the pass bands of the acoustic wave phase shift circuits 21A and 22A about −90° is difficult to achieve by simply changing the orientation of the IDT electrodes, and it is necessary to change, for example, the spacing between adjacent IDT electrodes. The ideal spacing between the IDT electrodes for the longitudinally coupled resonator filter to function as a band pass filter is about (λ/4+nλ/2: n=0, 1, 2, . . . ), and if the spacing between the IDT electrodes is changed for phase adjustment, the filter characteristics will deteriorate.

Although not indicated in the electrode parameters of Table 5, in order to make the phase difference between the pass bands of the acoustic wave phase shift circuits 21A and 22A about −90°, for example, a (narrow-period electrode finger) method is used in which, in a given IDT electrode, the spacing of the electrode finger close to the adjacent IDT electrode or the spacing of the electrode finger close to a reflector is smaller than the spacing between the electrode fingers of the given IDT electrode.

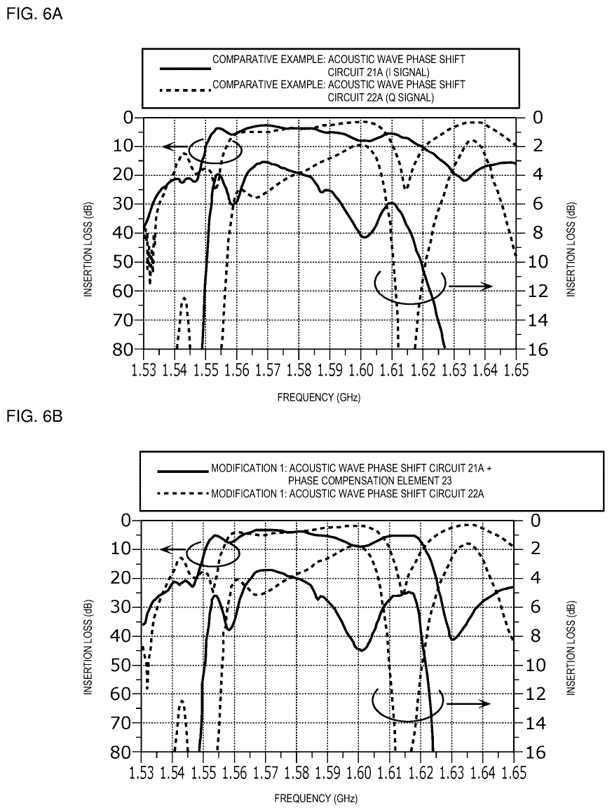

FIG. 6A is a graph showing the bandpass characteristics of an acoustic wave device according to a comparative example. FIG. 6B is a graph showing the bandpass characteristics of the acoustic wave device 20A according to Modification 1. The acoustic wave device according to the comparative example differs from the acoustic wave device 20A according to Modification 1 only in that the phase compensator 23 is not included.

As shown in FIGS. 6A and 6B, in the acoustic wave device, the pass band of the acoustic wave phase shift circuit 21A is wider than the pass band of the acoustic wave phase shift circuit 22A, and the pass band of the acoustic wave phase shift circuit 21A includes the pass band of the acoustic wave phase shift circuit 22A. By making the pass band width of the acoustic wave phase shift circuit 21A and the pass band width of the acoustic wave phase shift circuit 22A different as described above, the phase difference between the I signal and the Q signal over the pass bands can be adjusted with higher accuracy.

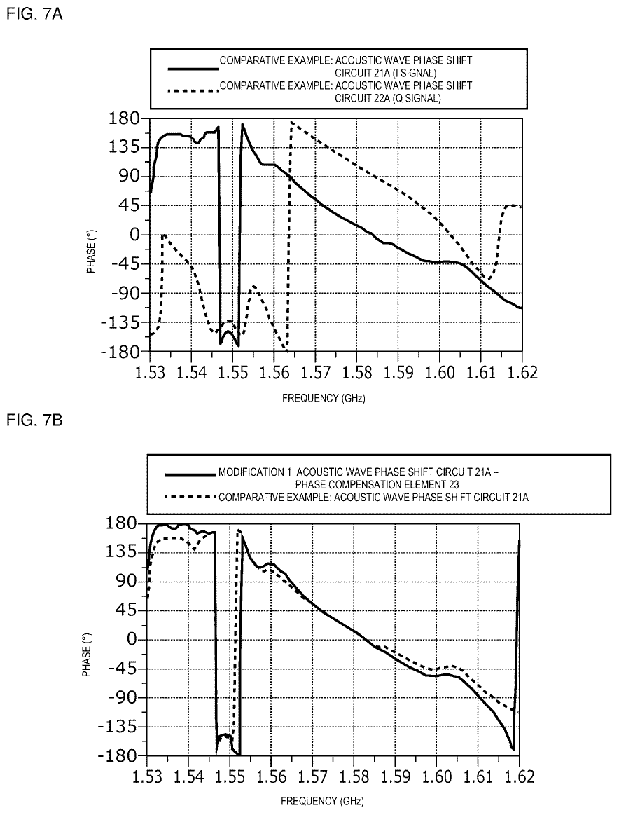

Specifically, the phase characteristics of the longitudinally coupled SAW filter change gradually from the low-frequency side to the high-frequency side of the pass bands (see, for example, FIG. 7A). The start point of the change region (referred to as “phase rise”) appears earlier (i.e., at a lower frequency side) in the acoustic wave phase shift circuit 21A, which has a wide pass band, and later (i.e., at a higher frequency side) in the acoustic wave phase shift circuit 22A, which has a narrow pass band. Because of such a relationship, the respective pass bands can be set so that the phase rise of the acoustic wave phase shift circuit 22A occurs at a frequency at which the acoustic wave phase shift circuit 21A has changed by about 90° from the phase rise thereof. In other words, by setting the pass band of the acoustic wave phase shift circuit 21A and the pass band of the acoustic wave phase shift circuit 22A so that the former includes the latter, the phase difference between the acoustic wave phase shift circuits 21A and 22A can be adjusted with high accuracy.

In the acoustic wave phase shift circuit 21A, which has a wide pass band width, the impedance tends to become capacitive, and the matching property with respect to the termination impedance deteriorates. To avoid such a problem, the acoustic wave phase shift circuit 21A has a larger intersecting width than the acoustic wave phase shift circuit 22A, which has a narrow pass band width.

FIG. 7A is a graph showing the phase characteristics of the acoustic wave device according to the comparative example. As shown in FIG. 7A, with regard to the amount of phase change in the pass bands of the acoustic wave phase shift circuit 21A and 22A, the amount of phase change in the pass band of the acoustic wave phase shift circuit 21A, which has a wide band, is smaller, and the amount of phase change in the pass band of the acoustic wave phase shift circuit 22A, which has a narrow band, is larger. Therefore, in the frequency band (in particular, the high-frequency side of the pass band of the acoustic wave phase shift circuit 22A) of the IQ signal, the phase difference between the acoustic wave phase shift circuits 21A and 22A deviates from 90° (for example, becomes smaller than about 90°).

FIG. 7B is a graph showing the phase characteristics of the I signal in the acoustic wave device according to Modification 1 and the acoustic wave device according to the comparative example. In the acoustic wave device 20A according to Modification 1, the phase compensator 23 is added on the output side of the acoustic wave phase shift circuit 21A. Therefore, in the phase characteristics of the path through which the I signal passes (the acoustic wave phase shift circuit 21A+the phase compensator 23), the phase changes on the high-frequency side and the low-frequency side of the pass band of the acoustic wave phase shift circuit 21A, compared with the phase characteristics of the acoustic wave phase shift circuit 21A according to the comparative example. In particular, the phase on the high-frequency side of the pass band of (the acoustic wave phase shift circuit 21A+the phase compensator 23) according to Modification 1 is smaller than the phase on the high-frequency side of the pass band of the acoustic wave phase shift circuit 21A according to the comparative example.

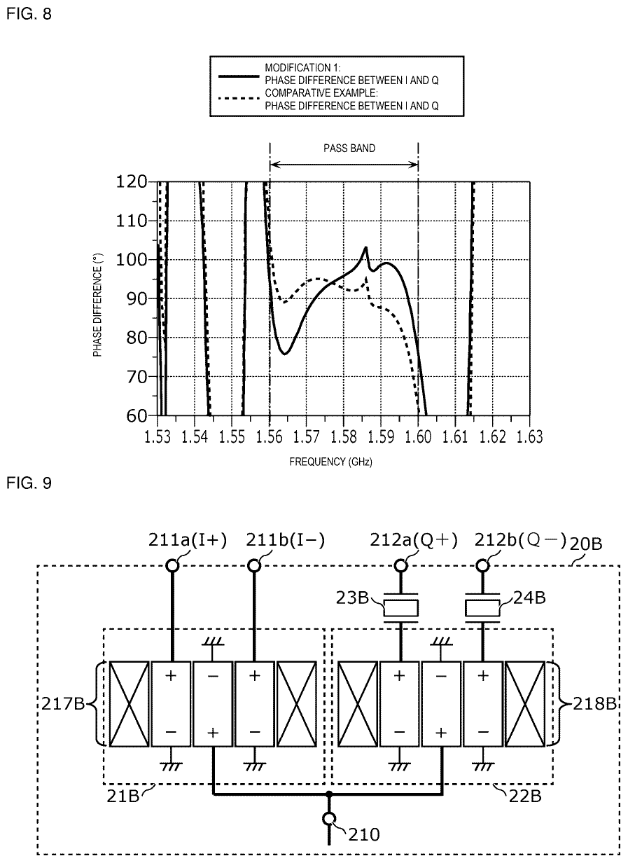

FIG. 8 is a graph showing the characteristics of the phase difference between the I signal and the Q signal in the acoustic wave device according to Modification 1 and the acoustic wave device according to the comparative example. The phase difference between the I signal and the Q signal in the acoustic wave device needs to be set at about 90° in the frequency band of the IQ signal. As shown in FIG. 8, the phase difference between the I signal and the Q signal (the phase difference between the acoustic wave phase shift circuit 21A and the acoustic wave phase shift circuit 22A) in the acoustic wave device according to the comparative example greatly deviates from 90° in the high-frequency side of the pass band (is greatly reduced from 90°). On the other hand, the phase difference between the I signal and the Q signal (the phase difference between the acoustic wave phase shift circuit 21A and the phase compensator 23 and the acoustic wave phase shift circuit 22A) in the acoustic wave device 20A according to Modification 1 is greatly improved in the high-frequency side of the pass band. Thus, in the acoustic wave device 20A according to Modification 1, the phase difference can be maintained around 90° over the entire pass band.

### 1.8 Circuit Configuration of Acoustic Wave Device 20B According to Modification 2

FIG. 9 is a circuit configuration diagram of an acoustic wave device 20B according to Modification 2 of an example embodiment of the present invention. The acoustic wave device 20B according to the present modification includes acoustic wave phase shift circuits 21B and 22B, phase compensators 23B and 24B, differential input I-terminals 211a and 211b, differential input Q-terminals 212a and 212b, and a non-differential output terminal 210.

The acoustic wave phase shift circuit 21B includes a longitudinally coupled SAW filter 217B including three IDT electrodes (referred to as a first IDT electrode, a second IDT electrode, and a third IDT electrode in an order from the left side in FIG. 9) and two reflectors disposed on a piezoelectric substrate. The acoustic wave phase shift circuit 22B includes a longitudinally coupled SAW filter 218B including three IDT electrodes (referred to as a first IDT electrode, a second IDT electrode, and a third IDT electrode in an order from the left side in FIG. 9) and two reflectors disposed on a piezoelectric substrate.

The +terminal of the first IDT electrode of the SAW filter 217B is connected to the input I-terminal 211a, the +terminal of the third IDT electrode of the SAW filter 217B is connected to the input I-terminal 211b, and the +terminal of the second IDT electrode of the SAW filter 217B is connected to the output terminal 210. The +terminal of the first IDT electrode of the SAW filter 218B is connected to the input Q-terminal 212a with the phase compensator 23B connected therebetween, the +terminal of the third IDT electrode of the SAW filter 218B is connected to the input Q-terminal 212b with the phase compensator 24B connected therebetween, and the +terminal of the second IDT electrode of the SAW filter 218B is connected to the output terminal 210. The −terminals of the SAW filters 217B and 218B are grounded.

With the configuration described above, the phase difference between the I signal and the Q signal (i.e., the phase difference between the acoustic wave phase shift circuit 21B and the acoustic wave phase shift circuit 22B) in the acoustic wave device 20B can be improved by including the phase compensators 23B and 24B. Thus, in the acoustic wave device 20B according to Modification 2, the phase difference can be maintained around 90° over the entire pass band.

### 1.9 Circuit Configuration of Acoustic Wave Device 20C According to the Modification 3

Next, an example of the circuit configuration of an acoustic wave device 20C according to Modification 3 of an example embodiment of the present invention is described.

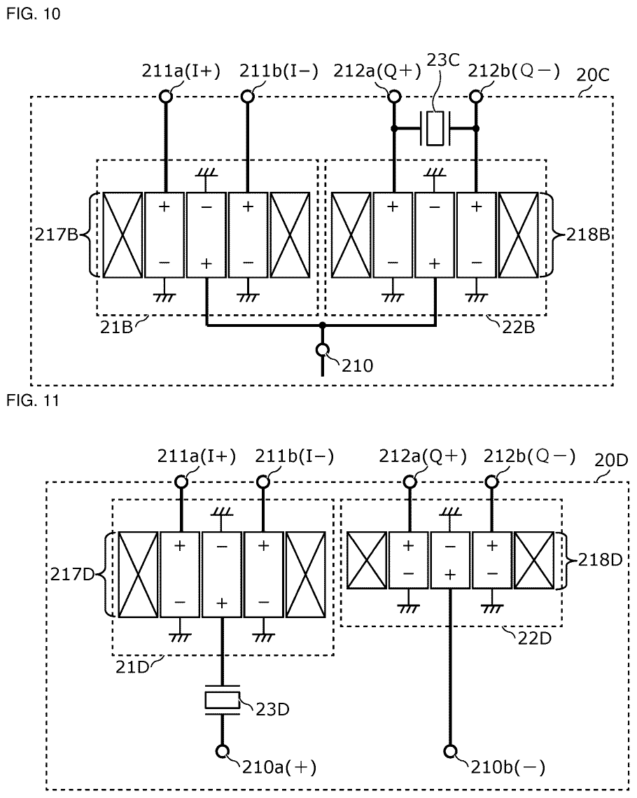

FIG. 10 is a circuit configuration diagram of an acoustic wave device 20C according to Modification 3. The acoustic wave device 20C according to the present modification includes acoustic wave phase shift circuits 21B and 22B, a phase compensator 23C, differential input I-terminals 211a and 211b, differential input Q-terminals 212a and 212b, and a non-differential output terminal 210. The acoustic wave device 20C according to the present modification differs from the acoustic wave device 20B according to Modification 2 only in that the phase compensator 23C is included instead of the phase compensators 23B and 24B. The following description of the acoustic wave device 20C according to the present modification will focus on the different points, and omit the description of the points that are the same or substantially the same as those of the acoustic wave device 20B according to Modification 2.

The +terminal of the first IDT electrode of the SAW filter 218B is connected to the input Q-terminal 212a, the +terminal of the third IDT electrode of the SAW filter 218B is connected to the input Q-terminal 212b, and the +terminal of the second IDT electrode of the SAW filter 218B is connected to the output terminal 210.

The phase compensator 23C is connected between the input Q-terminal 212a and the input Q-terminal 212b.

With the configuration described above, the phase difference between the I signal and the Q signal (i.e., the phase difference between the acoustic wave phase shift circuit 21B and the acoustic wave phase shift circuit 22B) in the acoustic wave device 20C can be improved by including the phase compensator 23C. Thus, in the acoustic wave device 20C according to Modification 3, the phase difference can be maintained around 90° over the entire pass band.

### 1.10 Circuit Configuration of Acoustic Wave Device 20D According to Modification 4

The output of the acoustic wave device may be a differential output.

FIG. 11 is a circuit configuration diagram of an acoustic wave device 20D according to Modification 4. The acoustic wave device 20D includes acoustic wave phase shift circuits 21D and 22D, input I-terminals 211a and 211b, input Q-terminals 212a and 212b, an output terminal 210a, and an output terminal 210b. The acoustic wave device 20D according to the present modification is connected to the quadrature mixer 10A shown in FIG. 4A. The acoustic wave device 20D has a different configuration of the output terminal compared with the acoustic wave device 20A according to Modification 1.

The output terminal 210a is an example of a first differential terminal. The output terminal 210a receives an I signal phase-adjusted by the acoustic wave phase shift circuit 21D. The output terminal 210b is an example of a second differential terminal. The output terminal 210b receives a Q signal phase-adjusted by the acoustic wave phase shift circuit 22D.

In such a case, a radio-frequency signal including a desired signal D_{P} and an image signal IM_{P} is inputted to the input terminal 110a, a radio-frequency signal including a desired signal D_{N} and an image signal IM_{N} is inputted to the input terminal 110b, and the radio-frequency signals are distributed to the mixer circuits 11A and 12A. At this time, desired signals D_{IP} and D_{IN} and image signals IM_{IP} and IM_{IN} inputted to the mixer circuit 11A are modulated to frequencies (−F_{IF}) and (+F_{IF}), so that the desired signal D_{IP} and the image signal IM_{IP} are in phase, and the desired signal D_{IN} and the image signal IM_{IN} are in phase. On the other hand, a desired signal D_{QP} and an image signal IM_{QP} inputted to the mixer circuit 12A are modulated to frequencies (−F_{IF}) and (+F_{IF}), the desired signal D_{QP} is rotated by about 90° (or about −90°) with respect to the desired signal D_{IP}, a desired signal D_{QN} is rotated by about 90° (or about −90°) with respect to the desired signal D_{IN}, the image signal IM_{QP} is rotated by about −90° (or about 90°) with respect to the image signal IM_{IP}, and an image signal IM_{QN} is rotated by about −90° (or about 90°) with respect to the image signal IM_{IN}.

Tables 6 and 7 indicate the relationships, for the desired signal D and the image signal IM, between the output signals outputted to the output terminals 210a and 210b, the phase of the local signal to be multiplied by the quadrature mixer 10A, and the phase rotation amount in the acoustic wave device 20D (the phase rotation amount of the acoustic wave phase shift circuit).

TABLE 6

| | | Local signal | | Output of mixer | Output phase |
|---|---|---|---|---|---|
| Signal | Input of mixer 10A | (phase) | Terminal | 104 | of mixer 10A |
| Desired signal D | $+ \frac{{A}_{RF}}{4} ( \text{?} + \text{?} )$ | $\frac{{e}^{j {ω}_{LO} t} + {e}^{- j {ω}_{LO} t}}{2} ( 0 )$ | I+ | $+ \frac{{A}_{RF}}{8} ( e \text{?} - e \text{?} )$ | 0 |
| | $- \frac{{A}_{RF}}{4} ( \text{?} + \text{?} )$ | $\frac{- {e}^{j {ω}_{LO} t} + {e}^{- j {ω}_{LO} t}}{2 j} ( π / 2 )$ | I− | $- \frac{{A}_{RF}}{8} ( e \text{?} - e \text{?} )$ | 0 |
| | $+ \frac{{A}_{RF}}{4} ( \text{?} + \text{?} )$ | | Q+ | $+ \frac{{A}_{RF}}{8 j} ( e \text{?} - e \text{?} )$ | $- \frac{π}{2}$ |
| | $- \frac{{A}_{RF}}{4} ( \text{?} + \text{?} )$ | | Q− | $- \frac{{A}_{RF}}{8 j} ( e \text{?} - e \text{?} )$ | $+ \frac{π}{2}$ |
| Image signal IM | $+ \frac{{A}_{IM}}{4} ( \text{?} + \text{?} )$ | $\frac{{e}^{j {ω}_{LO} t} + {e}^{- j {ω}_{LO} t}}{2} ( 0 )$ | I+ | $+ \frac{{A}_{IM}}{8} ( e \text{?} + e \text{?} )$ | 0 |
| | $- \frac{{A}_{IM}}{4} ( e \text{?} + e \text{?} )$ | $\frac{- {e}^{j {ω}_{LO} t} + {e}^{- j {ω}_{LO} t}}{2 j} ( π / 2 )$ | I− | $- \frac{{A}_{IM}}{8} ( e \text{?} + e \text{?} )$ | 0 |
| | $+ \frac{{A}_{IM}}{4} ( e \text{?} + e \text{?} )$ | | Q+ | $- \frac{{A}_{IM}}{8 j} ( e \text{?} - e \text{?} )$ | $+ \frac{π}{2}$ |
| | $- \frac{{A}_{IM}}{4} ( e \text{?} + e \text{?} )$ | | Q− | $+ \frac{{A}_{IM}}{8 j} ( e \text{?} - e \text{?} )$ | $- \frac{π}{2}$ |
| | | | Phase rotation amount | Output of acoustic | |
| | | | of acoustic wave | wave phase shift | Output of acoustic |
| | | Signal | phase shift circuit | circait | wave device 20A |
| | | Desired signal D | 0 | $+ {B}_{SAW} \frac{{A}_{RF}}{8} ( e \text{?} + e \text{?} )$ | $+ {B}_{SAW} \frac{{A}_{RF}}{4} ( e \text{?} + e \text{?} )$ |
| | | | π | $+ {B}_{SAW} \frac{{A}_{RF}}{8} e \text{?} + e \text{?} )$ | $- {B}_{SAW} \frac{{A}_{RF}}{4} ( e \text{?} + e \text{?} )$ |
| | | | $- \frac{π}{2}$ | $- {B}_{SAW} \frac{{A}_{RF}}{8} ( e \text{?} + e \text{?} )$ | |
| | | | $+ \frac{π}{2}$ | $- {B}_{SAW} \frac{{A}_{RF}}{8} ( e \text{?} + e \text{?} )$ | |
| | | Image signal IM | 0 | $+ {B}_{SAW} \frac{{A}_{IM}}{8} ( e \text{?} + e \text{?} )$ | $+ {B}_{SAW} \frac{{A}_{IM}}{4} ( e \text{?} + e \text{?} )$ |
| | | | π | $+ {B}_{SAW} \frac{{A}_{IM}}{8} ( e \text{?} + e \text{?} )$ | $+ {B}_{SAW} \frac{{A}_{IM}}{4} ( e \text{?} + e \text{?} )$ |
| | | | $- \frac{π}{2}$ | $+ {B}_{SAW} \frac{{A}_{IM}}{8} ( e \text{?} + e \text{?} )$ | |
| | | | $+ \frac{π}{2}$ | $+ {B}_{SAW} \frac{{A}_{IM}}{8} ( e \text{?} + e \text{?} )$ | |

F_{RF} = F_{LO} + F_{IF}, θ_{LOI} = 0°, θ_{LOQ} = +90°, mixer differential output, acoustic wave device differential input/non-differential output
$\text{?} \text{indicates text missing or illegible when filed}$

Table 6 indicates the conditions under which the desired signal D_{I}LO_{I} at the output terminal 210a and the desired signal D_{Q}LO_{Q} at the output terminal 210b are in opposite phase, and the image signal IM_{I}LO_{I} at the output terminal 210a and the image signal IM_{Q}LO_{Q} at the output terminal 210b are in phase, when the frequency of the desired signal D is F_{LO}+F_{IF} and the frequency of the image signal IM is F_{LO}−F_{IF}. In Table 6, when the phase rotation amount of the phase of the local signal LO_{Q} with respect to the local signal LO_{I} is about +90°, the phase rotation amount of the desired signal D_{QP} with respect to the desired signal D_{IP} is rotated by about −90° and the phase rotation amount of the desired signal D_{QN} with respect to the desired signal D_{IN} is rotated by about +90° in the acoustic wave phase shift circuit 22D. When the phase rotation amount of the phase of the local signal LO_{Q} with respect to the local signal LO_{I} is about −90°, the phase rotation amount of the desired signal D_{QP} with respect to the desired signal D_{IP} is rotated by about +90° and the phase rotation amount of the desired signal D_{QN} with respect to the desired signal D_{IN} is rotated by about −90° in the acoustic wave phase shift circuit 22D.

TABLE 7

| | | Local signal | | Output of mixer |
|---|---|---|---|---|
| Signal | Input of mixer 10A | (phase) | Terminal | 104 |
| Desired signal D | $+ \frac{{A}_{RF}}{4} ( e \text{?} + e \text{?} )$ | $\frac{{e}^{j {ω}_{LO} t} + {e}^{- j {ω}_{LO} t}}{2} ( 0 )$ | I+ | $+ \frac{{A}_{RF}}{8} ( e \text{?} + e \text{?} )$ |
| | $- \frac{{A}_{RF}}{4} ( e \text{?} + e \text{?} )$ | $\frac{- {e}^{j {ω}_{LO} t} + {e}^{- j {ω}_{LO} t}}{2 j} ( π / 2 )$ | I− | $- \frac{{A}_{RF}}{8} ( e \text{?} + e \text{?} )$ |
| | $+ \frac{{A}_{RF}}{4} ( e \text{?} + e \text{?} )$ | | Q+ | $- \frac{{A}_{RF}}{8 j} ( e \text{?} - e \text{?} )$ |
| | $- \frac{{A}_{RF}}{4} ( e \text{?} + e \text{?} )$ | | Q− | $+ \frac{{A}_{RF}}{8 j} ( e \text{?} - e \text{?} )$ |
| Image signal IM | $+ \frac{{A}_{IM}}{4} ( e \text{?} + e \text{?} )$ | $\frac{{e}^{j {ω}_{LO} t} + {e}^{- j {ω}_{LO} t}}{2} ( 0 )$ | I+ | $+ \frac{{A}_{IM}}{8} ( e \text{?} + e \text{?} )$ |
| | $- \frac{{A}_{IM}}{4} ( e \text{?} + e \text{?} )$ | $\frac{- {e}^{j {ω}_{LO} t} + {e}^{- j {ω}_{LO} t}}{2 j} ( π / 2 )$ | I− | $- \frac{{A}_{IM}}{8} ( e \text{?} + e \text{?} )$ |
| | $+ \frac{{A}_{IM}}{4} ( e \text{?} + e \text{?} )$ | | Q+ | $+ \frac{{A}_{IM}}{8 j} ( e \text{?} - e \text{?} )$ |
| | $- \frac{{A}_{IM}}{4} ( e \text{?} + e \text{?} )$ | | Q− | $- \frac{{A}_{IM}}{8 j} ( e \text{?} - e \text{?} )$ |
| | | Phase rotation amount | Output of acoustic | |
| | Output phase | of acoustic wave | wave phase shift | Output of acoustic |
| | of mixer 10A | phase shift circuit | circait | wave device 20A |
| Desired signal D | 0 | 0 | $+ {B}_{SAW} \frac{{A}_{RF}}{8} ( e \text{?} + e \text{?} )$ | $+ {B}_{SAW} \frac{{A}_{RF}}{4} ( e \text{?} + e \text{?} )$ |
| | 0 | π | $+ {B}_{SAW} \frac{{A}_{RF}}{8} ( e \text{?} + e \text{?} )$ | $- {B}_{SAW} \frac{{A}_{RF}}{4} ( e \text{?} + e \text{?} )$ |
| | $+ \frac{π}{2}$ | $+ \frac{π}{2}$ | $- {B}_{SAW} \frac{{A}_{RF}}{8} ( e \text{?} + e \text{?} )$ | |
| | $- \frac{π}{2}$ | $- \frac{π}{2}$ | $- {B}_{SAW} \frac{{A}_{RF}}{8} ( e \text{?} + e \text{?} )$ | |
| Image signal IM | 0 | 0 | $+ {B}_{SAW} \frac{{A}_{IM}}{8} ( e \text{?} + e \text{?} )$ | $+ {B}_{SAW} \frac{{A}_{IM}}{4} ( e \text{?} + e \text{?} )$ |
| | 0 | π | $+ {B}_{SAW} \frac{{A}_{IM}}{8} ( e \text{?} + e \text{?} )$ | $+ {B}_{SAW} \frac{{A}_{IM}}{4} ( e \text{?} + e \text{?} )$ |
| | $- \frac{π}{2}$ | $+ \frac{π}{2}$ | $+ {B}_{SAW} \frac{{A}_{IM}}{8} ( e \text{?} + e \text{?} )$ | |
| | $+ \frac{π}{2}$ | $- \frac{π}{2}$ | $+ {B}_{SAW} \frac{{A}_{IM}}{8} ( e \text{?} + e \text{?} )$ | |

F_{RF} = F_{LO} + F_{IF}, θ_{LOI} = 0°, θ_{LOQ} = +90°, mixer differential output, acoustic wave device differential input/non-differential output
$\text{?} \text{indicates text missing or illegible when filed}$

Table 7 indicates the conditions under which the desired signal D_{I}LO_{I} at the output terminal 210a and the desired signal D_{Q}LO_{Q} at the output terminal 210b are in opposite phase and the image signal IM_{I}LO_{I} at the output terminal 210a and the image signal IM_{Q}LO_{Q} at the output terminal 210b are in phase, when the frequency of the desired signal D is F_{LO}−F_{IF} and the frequency of the image signal IM is F_{LO}+F_{IF}. In Table 7, when the phase rotation amount of the phase of the local signal LO_{Q} with respect to the local signal LO_{I} is about +90°, the phase rotation amount of the desired signal D_{QP} with respect to the desired signal D_{IP} is rotated by about +90° and the phase rotation amount of the desired signal D_{QN} with respect to the desired signal D_{IN} is rotated by about −90° in the acoustic wave phase shift circuit 22D. Also, when the phase rotation amount of the phase of the local signal LO_{Q} with respect to the local signal LO_{I} is about −90°, the phase rotation amount of the desired signal D_{QP} with respect to the desired signal D_{IP} is rotated by about −90° and the phase rotation amount of the desired signal D_{QN} with respect to the desired signal D_{IN} is rotated by about +90° in the acoustic wave phase shift circuit 22D.

As indicated in Tables 6 and 7, when the phase difference between the local signals LO_{Q} and LO_{I} is a predetermined phase difference, ∞ is obtained as the image rejection ratio. Here, in the present modification, as in the receiver 1 according to the above-described example embodiment, the required image rejection ratio IRR is, for example about 10 dB.

At this time, in the acoustic wave device 20D according to the present modification, when the frequency of the desired signal D is F_{LO}+F_{IF} and the frequency of the image signal IM is F_{LO}−F_{IF}, the phase rotation amount of the I signal transmitted from the input I-terminal 211a and the input I-terminal 211b to the output terminal 210a is α°. Further, for example, the phase rotation amount of the I_{P} signal transmitted from the input I-terminal 211a to the output terminal 210a is equal to or greater than (α+n×360-35.1)° and equal to or less than (α+n×360+35.1)°, and the phase rotation amount of the I_{N} signal transmitted from the input I-terminal 211b to the output terminal 210a equal to or greater than (α+180+n×360−35.1)° and equal to or less than (α+180+n×360+35.1)°. At this time, when the value obtained by subtracting the phase of the local signal that drives the mixer circuit 11A from the phase of the local signal that drives the mixer circuit 12A is (+90+n×360)°, and the phase rotation amount of the Q_{P} signal transmitted from the input Q-terminal 212a to the output terminal 210b is β3° and the phase rotation amount of the Q_{N} signal transmitted from the input Q-terminal 212b to the output terminal 210b is β4°, the relationship expressed as Expression 22 is satisfied.

$$( α - 90 + n \times 360 - 35.1 ) \leq β 3 \leq ( α - 90 + n \times 360 + 35.1 ) \qquad ( Expression 22 )$$

$$( α + 90 + n \times 360 - 35.1 ) \leq β 4 \leq ( α + 90 + n \times 360 + 35.1 )$$

When the value obtained by subtracting the phase of the local signal that drives the mixer circuit 11A from the phase of the local signal that drives the mixer circuit 12A is (−90+n×360)°, the relationship expressed as Expression 23 is satisfied.

$$( α + 90 + n \times 360 - 35.1 ) \leq β 3 \leq ( α + 90 + n \times 360 + 35.1 ) \qquad ( Expression 23 )$$

$$( α - 90 + n \times 360 - 35.1 ) \leq β 4 \leq ( α - 90 + n \times 360 + 35.1 )$$

Thus, the image signal IM generated by the quadrature mixer 10A can be reduced or prevented by the acoustic wave device 20D at an image rejection ratio of about 10 dB or more. Further, instead of providing circuit elements such as baluns and transformers, the acoustic wave device 20D for phase adjustment is provided between the output end of the quadrature mixer 10A and the signal output terminal 102. Therefore, it is possible to provide a miniaturized mixer-first receiver with low loss.

Further, the frequency F_{RF} (=F_{LO}+F_{IF}) of the radio-frequency signal can be changed by changing the frequency F_{LO} of the local signal. Further, for example, a quadrature mixer 10A including a double balanced mixer with excellent performance can be used as a semiconductor circuit.

Further, in the acoustic wave device 20D according to the present modification, when the frequency of the desired signal D is F_{LO}−F_{IF} and the frequency of the image signal IM is F_{LO}+F_{IF}, the phase rotation amount of the I signal transmitted from the input I-terminal 211a and the input I-terminal 211b to the output terminal 210a is α°. Further, for example, the phase rotation amount of the I_{P} signal transmitted from the input I-terminal 211a to the output terminal 210a is equal to or greater than (α+n×360−35.1)° and equal to or less than (α+n×360+35.1)°, and the phase rotation amount of the I_{N} signal transmitted from the input I-terminal 211b to the output terminal 210a is equal to or greater than (α+180+n×360−35.1)° and equal to or less than (α+180+n×360+35.1)°. At this time, when the value obtained by subtracting the phase of the local signal that drives the mixer circuit 11A from the phase of the local signal that drives the mixer circuit 12A is (+90+n×360)°, and the phase rotation amount of the Q_{P} signal transmitted from the input Q-terminal 212a to the output terminal 210b is β3° and the phase rotation amount of the Q_{N} signal transmitted from the input Q-terminal 212b to the output terminal 210b is β4°, the relationship expressed as Expression 23 is satisfied.

Also, when the value obtained by subtracting the phase of the local signal that drives the mixer circuit 11A from the phase of the local signal that drives the mixer circuit 12A is (−90+n×360)°, the relationship expressed as Expression 22 is satisfied.

Thus, the frequency F_{RF} (=F_{LO}−F_{IF}) of the radio-frequency signal can be changed by changing the frequency F_{LO} of the local signal.

Returning to FIG. 11, the circuit configuration of the acoustic wave device 20D will be described. The acoustic wave device 20D includes the acoustic wave phase shift circuits 21D and 22D, a phase compensator 23D, differential input I-terminals 211a and 211b, differential input Q-terminals 212a and 212b, and differential output terminals 210a and 210b.

The acoustic wave phase shift circuit 21D includes a longitudinally coupled SAW filter 217D including three IDT electrodes (referred to as a first IDT electrode, a second IDT electrode, and a third IDT electrode in an order from the left side in FIG. 11) and two reflectors disposed on a piezoelectric substrate. The acoustic wave phase shift circuit 22D includes a longitudinally coupled SAW filter 218D including three IDT electrodes (referred to as a first IDT electrode, a second IDT electrode, and a third IDT electrode in an order from the left side in FIG. 11) and two reflectors disposed on a piezoelectric substrate.

The +terminal of the first IDT electrode of the SAW filter 217D is connected to the input I-terminal 211a, the +terminal of the third IDT electrode of the SAW filter 217D is connected to the input I-terminal 211b, and the +terminal of the second IDT electrode of the SAW filter 217D is connected to the output terminal 210a with the phase compensator 23D connected therebetween. The +terminal of the first IDT electrode of the SAW filter 218D is connected to the input Q-terminal 212a, the +terminal of the third IDT electrode of the SAW filter 218D is connected to the input Q-terminal 212b, and the +terminal of the second IDT electrode of the SAW filter 218D is connected to the output terminal 210b. The −terminals of the SAW filters 217D and 218D are grounded.

With the configuration described above, the phase difference between the I signal and the Q signal (i.e., the phase difference between the acoustic wave phase shift circuit 21D and the acoustic wave phase shift circuit 22D) in the acoustic wave device 20D can be improved by including the phase compensator 23D. Thus, in the acoustic wave device 20D according to Modification 4, the phase difference can be maintained around 90° over the entire pass band.

Further, since the output terminal is a differential terminal, it is less affected by noise and high attenuation can be obtained.

### 1.11 Circuit Configuration of Acoustic Wave Device 20E According to Modification 5

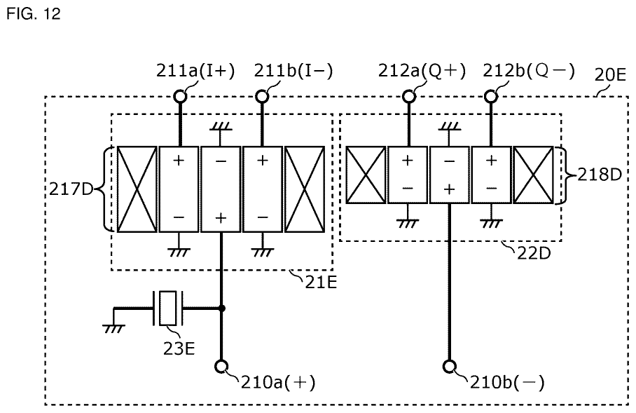

FIG. 12 is a circuit configuration diagram of an acoustic wave device 20E according to Modification 5 of an example embodiment of the present invention. The acoustic wave device 20E according to the present modification includes acoustic wave phase shift circuits 21E and 22D, a phase compensator 23E, differential input I-terminals 211a and 211b, differential input Q-terminals 212a and 212b, and differential output terminals 210a and 210b. The acoustic wave device 20E according to the present modification is different from the acoustic wave device 20D according to Modification 4 only in that the phase compensator 23E is added instead of the phase compensator 23D. The following description of the acoustic wave device 20E according to the present modification will focus on the different points, and omit the description of the points that are the same or substantially the same as those of the acoustic wave device 20D according to Modification 4.

The acoustic wave phase shift circuit 21E includes a longitudinally coupled SAW filter 217D including three IDT electrodes (referred to as a first IDT electrode, a second IDT electrode, and a third IDT electrode in an order from the left side in FIG. 12) and two reflectors disposed on a piezoelectric substrate.

The +terminal of the first IDT electrode of the SAW filter 217D is connected to the input I-terminal 211a, the +terminal of the third IDT electrode of the SAW filter 217D is connected to the input I-terminal 211b, and the +terminal of the second IDT electrode of the SAW filter 217D is connected to the output terminal 210a.

The phase compensator 23E is connected between the output terminal 210a and ground.

With the configuration described above, the phase difference between the I signal and the Q signal (the phase difference between the acoustic wave phase shift circuit 21E and the acoustic wave phase shift circuit 22D) in the acoustic wave device 20E can be improved by adding the phase compensator 23E. Thus, in the acoustic wave device 20E according to Modification 5, the phase difference can be maintained around 90° over the entire pass band.

Further, since the output terminal is a differential terminal, it is less affected by noise and high attenuation can be obtained.

### 1.12 Circuit Configuration of Acoustic Wave Device 20F According to Modification 6

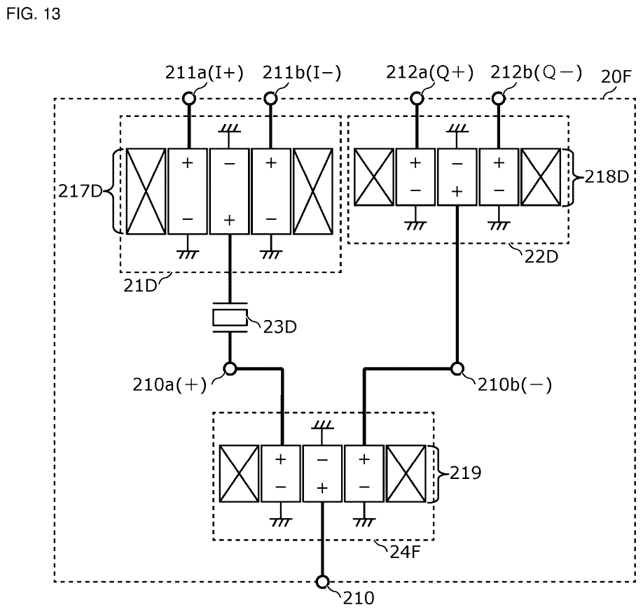

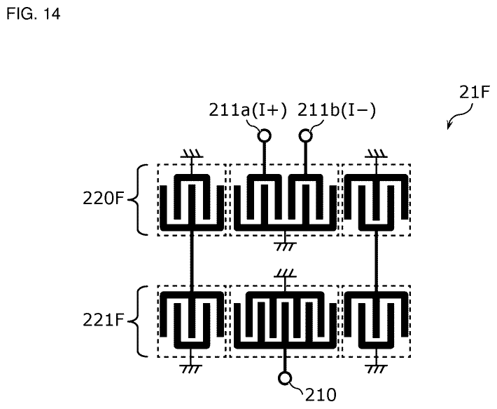

FIG. 13 is a circuit configuration diagram of an acoustic wave device 20F according to Modification 6 of an example embodiment of the present invention. The acoustic wave device 20F according to the present modification includes acoustic wave phase shift circuits 21D and 22D, a phase compensator 23D, an acoustic wave filter 24F, differential input I-terminals 211a and 211b, differential input Q-terminals 212a and 212b, and a non-differential output terminal 210. The acoustic wave device 20F according to the present modification differs from the acoustic wave device 20D according to Modification 4 in that the output terminal is a non-differential terminal and the acoustic wave filter 24F is included. The following description of the acoustic wave device 20F according to the present modification will focus on the different points, and omit the description of the points that are the same or substantially the same as those of the acoustic wave device 20D according to Modification 4.

The acoustic wave filter 24F is an example of an acoustic wave element including two balanced input terminals and one non-balanced output terminal. The acoustic wave filter 24F converts a balanced (differential) signal into a non-balanced (non-differential) signal. The acoustic wave filter 24F includes a longitudinally coupled SAW filter 219 including three IDT electrodes (referred to as a first IDT electrode, a second IDT electrode, and a third IDT electrode in an order from the left side in FIG. 13) and two reflectors disposed on a piezoelectric substrate.

The +terminal (balanced input terminal) of the first IDT electrode of the SAW filter 219 is connected to the acoustic wave phase shift circuit 21D with the phase compensator 23D connected therebetween, the +terminal (balanced input terminal) of the third IDT electrode of the SAW filter 219 is connected to the acoustic wave phase shift circuit 22D, and the +terminal (non-balanced output terminal) of the second IDT electrode of the SAW filter 219 is connected to the output terminal 210. The −terminal of the SAW filter 219 is grounded.

With the configuration described above, the I signal that has passed through the acoustic wave phase shift circuit 21D and the Q signal that has passed through the acoustic wave phase shift circuit 22D are differential signals, but the differential signals are converted into a non-differential signal by the acoustic wave filter 24F and outputted from the acoustic wave filter 24F. The acoustic wave filter 24F is miniaturized and emits less noise compared with a coil such as a transformer or balun, for example, which is a balance/non-balance conversion element. Further, by providing the acoustic wave filter 24F with the characteristics of a band pass filter, since the acoustic wave filter 24F is cascade-connected to the acoustic wave phase shift circuits 21D and 22D having the characteristics of a band pass filter, an acoustic wave device 20F having high attenuation can be provided.

### 1.13 Circuit Configuration of Acoustic Wave Phase Shift Circuit 21F According to Modification 7

FIG. 14 is a circuit configuration diagram of an acoustic wave phase shift circuit 21F according to Modification 7 of an example embodiment of the present invention. The acoustic wave phase shift circuit 21F includes a longitudinally coupled SAW filter 220F including three IDT electrodes (referred to as a first IDT electrode, a second IDT electrode, and a third IDT electrode in an order from the left side in FIG. 14) and two reflectors disposed on a piezoelectric substrate, and a longitudinally coupled SAW filter 221F including three IDT electrodes (referred to as a first IDT electrode, a second IDT electrode, and a third IDT electrode in an order from the left side in FIG. 14) and two reflectors disposed on a piezoelectric substrate.

One +terminal of the second IDT electrode of the SAW filter 220F is connected to the input I-terminal 211a, and the other +terminal of the second IDT electrode of the SAW filter 220F is connected to the input I-terminal 211b. The +terminal of the first IDT electrode of the SAW filter 220F is connected to the +terminal of the first IDT electrode of the SAW filter 221F, and the +terminal of the third IDT electrode of the SAW filter 220F is connected to the +terminal of the third IDT electrode of the SAW filter 221F. One +terminal of the second IDT electrode of the SAW filter 221F is connected to the output terminal 210.

In the acoustic wave phase shift circuit 21A according to Modification 1, the +terminals of different IDT electrodes are connected to two differential input I-terminals 211a and 211b, respectively, while in the acoustic wave phase shift circuit 21F, two +terminals of one IDT electrode of the SAW filter 220F are connected to two differential input I-terminals 211a and 211b, respectively. By adjusting the arrangement of the electrode fingers in the IDT electrode, a differential signal can be received by one IDT electrode.

### 2. Advantageous Effects and the Like

As described above, the acoustic wave device 20 according to the above-described example embodiment includes an input I-terminal 211 and an input Q-terminal 212 that respectively receive an I signal and a Q signal having a phase difference of about 90° to each other, an output terminal 210, an acoustic wave phase shift circuit 21 that is connected between the input I-terminal 211 and the output terminal 210, that includes an acoustic wave resonator, and that adjusts the phase of the I signal, an acoustic wave phase shift circuit 22 that is connected between the input Q-terminal 212 and the output terminal 210, that includes an acoustic wave resonator, and that adjusts the phase of the Q signal, and a phase compensator 23 that is connected to at least one of (1) between the input I-terminal 211 and the acoustic wave phase shift circuit 21, (2) between the input Q-terminal 212 and the acoustic wave phase shift circuit 22, (3) between the output terminal 210 and the acoustic wave phase shift circuit 21, and (4) between the output terminal 210 and the acoustic wave phase shift circuit 22.

When the I signal and Q signal are phase-adjusted by the phase shift circuit and combined at the output terminal 210, it is required that the phase difference between the I signal and Q signal is uniform over the frequency range of the I signal and Q signal (the pass band of the acoustic wave device 20). With the configuration described above, since the acoustic wave phase shift circuits 21 and 22 including an acoustic wave resonator are used as circuits for phase adjustment and balance/non-balance conversion, the circuit for phase-adjusting the I signal and Q signal can be achieved with small size and low loss. Further, since the phase compensator 23 is added between the I signal terminal and the Q signal terminal and the output terminal 210, the phase difference between the I signal and the Q signal at the output terminal 210 can be maintained uniform over the pass band of the acoustic wave device 20, and image components included in the IQ signal can be accurately reduced or prevented. Therefore, it is possible to provide a miniaturized acoustic wave device 20 capable of performing phase adjustment with low loss and high accuracy.

For example, in the acoustic wave device 20, the phase compensator 23 is an acoustic wave resonator.

With such a configuration, since the phase compensator 23 includes an acoustic wave element together with the acoustic wave phase shift circuits 21 and 22, the acoustic wave device 20 can be miniaturized, and the attenuation and steepness near the pass band can be increased.

For example, in the acoustic wave device 20A according to Modification 1, the I signal includes an I_{P} signal and an I_{N} signal in opposite phases to each other, the Q signal includes a Q_{P} signal and a Q_{N} signal in opposite phases to each other, the input I-terminal includes an input I-terminal 211a that receives the I_{P} signal and an input I-terminal 211b that receives the I_{N} signal, and the input Q-terminal includes an input Q-terminal 212a that receives the Q_{P} signal and an input Q-terminal 212b that receives the Q_{N} signal.

With such a configuration, since each of the input I-terminal and the input Q-terminal is a differential terminal, it is possible to directly connect a double balanced quadrature mixer using, for example, a Gilbert cell mixer or the like, which has excellent noise characteristics and is easy to obtain in a CMOS circuit, and the acoustic wave device 20A without connecting a differential/non-differential conversion element, such as a transformer including a coil of large size, therebetween. Therefore, it is possible to provide a miniaturized acoustic wave device 20A with low noise and a simplified configuration on the input side.

For example, in the acoustic wave device 20A (20B, 20C, 20F), the output terminal is a non-differential terminal that receives a signal obtained by combining an I signal phase-adjusted by the acoustic wave phase shift circuit 21A (21B, 21D) and a Q signal phase-adjusted by the acoustic wave phase shift circuit 22A (22B, 22D).

With such a configuration, since the output terminal is a non-differential terminal, it is not necessary to add a differential/non-differential conversion element separately. Further, since the number of connections to semiconductor devices, such as amplifiers, for example, connected to the output terminal can be reduced, it is possible to provide a miniaturized acoustic wave device with a simplified configuration on the output side.

For example, the acoustic wave device 20F further includes an acoustic wave filter 24F including two balanced input terminals and one non-balanced output terminal, in which one of the two balanced input terminals is connected to the acoustic wave phase shift circuit 21D, the other of the two balanced input terminals is connected to the acoustic wave phase shift circuit 22D, and the non-balanced output terminal is connected to the output terminal 210.

With such a configuration, the I signal that has passed through the acoustic wave phase shift circuit 21D and the Q signal that has passed through the acoustic wave phase shift circuit 22D are differential signals, but the differential signals are converted into a non-differential signal by the acoustic wave filter 24F and outputted from the acoustic wave filter 24F. Thus, the acoustic wave filter 24F is miniaturized and emits less noise compared with a coil such as, for example, a transformer or balun, which is a balance/non-balance conversion element.

In the acoustic wave device 20D (20E), for example, the output terminal includes a differential output terminal 210a that receives an I signal phase-adjusted by the acoustic wave phase shift circuit 21D (21E), and a differential output terminal 210b that receives a Q signal phase-adjusted by the acoustic wave phase shift circuit 22D.

With such a configuration, since the output terminal is a differential terminal, it is less affected by noise and high attenuation can be obtained.

In the acoustic wave device 20, for example, each of the acoustic wave phase shift circuits 21 and 22 has a band pass filter characteristic, and the pass band of the acoustic wave phase shift circuit 21 includes the pass band of the acoustic wave phase shift circuit 22, or the pass band of the acoustic wave phase shift circuit 22 includes the pass band of the acoustic wave phase shift circuit 21.

With such a configuration, the acoustic wave phase shift circuits 21 and 22 can match the phase difference between the I signal and the Q signal with higher accuracy over the pass band.

In the acoustic wave device 20, for example, at least one of the acoustic wave phase shift circuits 21 and 22 includes a longitudinally coupled surface acoustic wave filter.

With such a configuration, a miniaturized acoustic wave device 20 with high attenuation can be provided.

For example, in the acoustic wave devices 20A to 20E, the acoustic wave phase shift circuit 21A (21B, 21D, 21E) includes an IDT electrode and includes a longitudinally coupled surface acoustic wave filter whose pass band includes the frequency of the I signal, the acoustic wave phase shift circuit 22A (22B, 22D) includes an IDT electrode and includes a longitudinally coupled surface acoustic wave filter whose pass band includes the frequency of the Q signal, and the intersecting width of the IDT electrode of the acoustic wave phase shift circuit 21A (21B, 21D, 21E) is different from the intersecting width of the IDT electrode of the acoustic wave phase shift circuit 22A (22B, 22D).

With such a configuration, the degree of freedom to adjust the impedance of the acoustic wave phase shift circuit is increased, and the accuracy of impedance matching can be improved.

Further, a receiver 1 according to an example embodiment includes a quadrature mixer 10 that performs frequency conversion to convert a radio-frequency signal into an I signal and a Q signal having a phase difference of about 90° from each other, and an acoustic wave device 20 that receives the I signal at the input I-terminal 211 and the Q signal at the input Q-terminal 212.

With such a configuration, it is possible to provide a miniaturized receiver 1 that can reduce or prevent the image components of the IQ signal generated by the quadrature mixer 10 with high accuracy.

A communication device 5 according to an example embodiment includes an RFIC 3 that processes a radio-frequency signal, and a receiver 1 that transmits the radio-frequency signal between the RFIC 3 and an antenna 4.

With such a configuration, the advantageous effects of the receiver 1 can be obtained by the communication device 5.

### OTHER EXAMPLE EMBODIMENTS

The acoustic wave devices, the receivers, and the communication devices according to the present invention have been described with reference to example embodiments, examples and modifications. However, the present invention is not limited to the example embodiments, examples, and modifications described above. The present invention also includes modifications obtained by applying various modifications to the example embodiments, examples, and modifications conceived by those skilled in the art without departing from the scope of the present invention, and various devices incorporating the acoustic wave devices, the receivers, and the communication devices according to example embodiments of the present invention.

Further, for example, in the acoustic wave devices, the receivers, and the communication devices according to the example embodiments, examples and modifications described above, matching elements, such as, for example, inductors and capacitors and/or the like, and/or switch circuits may be connected between the respective components.

In the example embodiment described above, the acoustic wave may include, for example, surface acoustic wave(s), pseudo surface acoustic wave(s), boundary acoustic wave(s) and/or plate acoustic wave(s). The acoustic wave in the example embodiment described above may be an acoustic wave that can be excited by IDT electrode(s).

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
an I signal terminal and a Q signal terminal to respectively receive an I signal and a Q signal having a phase difference of about 90° from each other;
an output terminal;
a first phase shift circuit connected between the I signal terminal and the output terminal, including an acoustic wave resonator, and to adjust a phase of the I signal;
a second phase shift circuit connected between the Q signal terminal and the output terminal, including an acoustic wave resonator, and to adjust a phase of the Q signal; and
a phase compensator connected to at least one of between the I signal terminal and the first phase shift circuit, between the Q signal terminal and the second phase shift circuit, between the output terminal and the first phase shift circuit, and between the output terminal and the second phase shift circuit.

2. The acoustic wave device according to claim 1, wherein the phase compensator includes an acoustic wave resonator.

3. The acoustic wave device according to claim 1, wherein
the I signal includes an I_{P} signal and an I_{N} signal in opposite phase to each other;
the Q signal includes a Q_{P} signal and a Q_{N} signal in opposite phase to each other;
the I signal terminal includes an I_{P} signal terminal to receive the I_{P} signal and an I_{N} signal terminal to receive the I_{N} signal; and
the Q signal terminal includes a Q_{P} signal terminal to receive the Q_{P} signal and a Q_{N} signal terminal to receive the Q_{N} signal.

4. The acoustic wave device according to claim 1, wherein the output terminal is a non-differential terminal to receive a signal obtained by combining an I signal phase-adjusted by the first phase shift circuit and a Q signal phase-adjusted by the second phase shift circuit.

5. The acoustic wave device according to claim 4, further comprising:
an acoustic wave element including two balanced input terminals and one non-balanced output terminal; wherein
one of the two balanced input terminals is connected to the first phase shift circuit, another of the two balanced input terminals is connected to the second phase shift circuit, and the non-balanced output terminal is connected to the output terminal.

6. The acoustic wave device according to claim 1, wherein the output terminal includes a first differential terminal to receive an I signal phase-adjusted by the first phase shift circuit and a second differential terminal to receive a Q signal phase-adjusted by the second phase shift circuit.

7. The acoustic wave device according to claim 1, wherein
each of the first phase shift circuit and the second phase shift circuit includes a band pass filter characteristic; and
a pass band of the first phase shift circuit includes a pass band of the second phase shift circuit, or the pass band of the second phase shift circuit includes the pass band of the first phase shift circuit.

8. The acoustic wave device according to claim 1, wherein at least one of the first phase shift circuit and the second phase shift circuit includes a longitudinally coupled surface acoustic wave filter.

9. The acoustic wave device according to claim 8, wherein
the first phase shift circuit includes an IDT electrode, and a longitudinally coupled surface acoustic wave filter with a pass band including a frequency of the I signal;
the second phase shift circuit includes an IDT electrode, and a longitudinally coupled surface acoustic wave filter with a pass band including a frequency of the Q signal; and
an intersecting width of the IDT electrode of the first phase shift circuit is different from an intersecting width of the IDT electrode of the second phase shift circuit.

10. A receiver comprising:
a quadrature mixer to perform frequency conversion to convert a radio-frequency signal into an I signal and a Q signal with a phase difference of about 90° from each other; and
the acoustic wave device according to claim 1 to receive the I signal at the I signal terminal and receive the Q signal at the Q signal terminal.

11. The receiver according to claim 10, wherein in the acoustic wave device, a relationship expressed as
$$( α + 90 + n \times 360 - 35.1 ) \leq β \leq ( α + 90 + n \times 360 + 35.1 )$$
$$or$$
$$( α - 90 + n \times 360 - 35.1 ) \leq β \leq ( α - 90 + n \times 360 + 35.1 )$$
is satisfied, where α° represents a phase rotation amount of the I signal, β° represents a phase rotation amount of the Q signal, and n is an integer.

12. The receiver according to claim 11, wherein
the I signal includes an I_{P} signal and an I_{N} signal in opposite phase to each other;
the Q signal includes a Q_{P} signal and a Q_{N} signal in opposite phase to each other;
the quadrature mixer includes:
a first differential input terminal and a second differential input terminal to which signals with opposite phases to each other are inputted;
a first differential output I-terminal from which the I_{P} signal is outputted, and a second differential output I-terminal from which the I_{N} signal is outputted;
a first differential output Q-terminal from which the Q_{P} signal is outputted, and a second differential output Q-terminal from which the Q_{N} signal is outputted;
a first mixer connected between the first differential input terminal and second differential input terminal and the first differential output I-terminal and second differential output I-terminal; and
a second mixer connected between the first differential input terminal and second differential input terminal and the first differential output Q-terminal and second differential output Q-terminal;
the acoustic wave device includes:
an I_{P} signal terminal and an I_{N} signal terminal;
a Q_{P} signal terminal and a Q_{N} signal terminal; and
an output terminal;
the I_{P} signal terminal is connected to the first differential output I-terminal;
the I_{N} signal terminal is connected to the second differential output I-terminal;
the Q_{P} signal terminal is connected to the first differential output Q-terminal;
the Q_{N} signal terminal is connected to the second differential output Q-terminal;
in the acoustic wave device, where a phase rotation amount of the I signal transmitted from the I_{P} signal terminal and the I_{N} signal terminal to the output terminal is α°:
a phase rotation amount of the I_{P} signal transmitted from the I_{P} signal terminal to the output terminal is equal to or greater than (α+n×360−35.1)° and equal to or less than (α+n×360+35.1)°; and
a phase rotation amount of the I_{N} signal transmitted from the I_{N} signal terminal to the output terminal is equal to or greater than (α+180+n×360−35.1)° and equal to or less than (α+180+n×360+35.1)°;
when a value obtained by subtracting a phase of a local signal to drive the first mixer from a phase of a local signal that drives the second mixer is (+90+n×360)°, a relationship expressed as
$$( α + 90 + n \times 360 - 35.1 ) \leq β1 \leq ( α + 90 + n \times 360 + 35.1 ) ,$$
$$and$$
$$( α - 90 + n \times 360 - 35.1 ) \leq β2 \leq ( α - 90 + n \times 360 + 35.1 )$$
is satisfied; and
when a value obtained by subtracting the phase of the local signal that drives the first mixer from the phase of the local signal that drives the second mixer is (−90+n×360)°, a relationship expressed as
$$( α - 90 + n \times 360 - 35.1 ) \leq β1 \leq ( α - 90 + n \times 360 + 35.1 ) ,$$
$$and$$
$$( α + 90 + n \times 360 - 35.1 ) \leq β2 \leq ( α + 90 + n \times 360 + 35.1 )$$
is satisfied, where β1° represents a phase rotation amount of the Q_{P} signal transmitted from the Q_{P} signal terminal to the output terminal, and β2° represents a phase rotation amount of the Q_{N} signal transmitted from the Q_{N} signal terminal to the output terminal.

13. The receiver according to claim 11, wherein
the I signal includes an I_{P} signal and an I_{N} signal in opposite phase to each other;
the Q signal includes a Q_{P} signal and a Q_{N} signal in opposite phase to each other;
the quadrature mixer includes:
a first differential input terminal and a second differential input terminal to which signals with opposite phases to each other are inputted;
a first differential output I-terminal from which the I_{P} signal is outputted, and a second differential output I-terminal from which the I_{N} signal is outputted;
a first differential output Q-terminal from which the Q_{P} signal is outputted, and a second differential output Q-terminal from which the Q_{N} signal is outputted;
a first mixer connected between the first differential input terminal and second differential input terminal and the first differential output I-terminal and second differential output I-terminal; and
a second mixer connected between the first differential input terminal and second differential input terminal and the first differential output Q-terminal and second differential output Q-terminal;
the acoustic wave device includes:
an I_{P} signal terminal and an I_{N} signal terminal;
a Q_{P} signal terminal and a Q_{N} signal terminal; and
an output terminal;
the I_{P} signal terminal is connected to the first differential output I-terminal;
the I_{N} signal terminal is connected to the second differential output I-terminal;
the Q_{P} signal terminal is connected to the first differential output Q-terminal;
the Q_{N} signal terminal is connected to the second differential output Q-terminal;
in the acoustic wave device, where a phase rotation amount of the I signal transmitted from the I_{P} signal terminal and the I_{N} signal terminal to the output terminal is α°;
a phase rotation amount of the I_{P} signal transmitted from the I_{P} signal terminal to the output terminal is equal to or greater than (α+n×360−35.1)° and equal to or less than (α+n×360+35.1)°; and
a phase rotation amount of the I_{N} signal transmitted from the I_{N} signal terminal to the output terminal is equal to or greater than (α+180+n×360−35.1)° and equal to or less than (α+180+n×360+35.1)°;
when a value obtained by subtracting a phase of a local signal that drives the first mixer from a phase of a local signal that drives the second mixer is (+90+n×360)°, a relationship expressed as
$$( α - 90 + n \times 360 - 35.1 ) \leq β1 \leq ( α - 90 + n \times 360 + 35.1 ) ,$$
$$and$$
$$( α + 90 + n \times 360 - 35.1 ) \leq β2 \leq ( α + 90 + n \times 360 + 35.1 )$$
is satisfied; and
when a value obtained by subtracting the phase of the local signal that drives the first mixer from the phase of the local signal that drives the second mixer is (−90+n×360)°, a relationship expressed as
$$( α + 90 + n \times 360 - 35.1 ) \leq β1 \leq ( α + 90 + n \times 360 + 35.1 ) ,$$
$$and$$
$$( α - 90 + n \times 360 - 35.1 ) \leq β2 \leq ( α - 90 + n \times 360 + 35.1 )$$
is satisfied, where β1° represents a phase rotation amount of the Q_{P} signal transmitted from the Q_{P} signal terminal to the output terminal, and β2° represents a phase rotation amount of the Q_{N} signal transmitted from the Q_{N} signal terminal to the output terminal.

14. The receiver according to claim 11, wherein
the I signal includes an I_{P} signal and an I_{N} signal in opposite phase to each other;
the Q signal includes a Q_{P} signal and a Q_{N} signal in opposite phase to each other;
the quadrature mixer includes:
a first differential input terminal and a second differential input terminal to which signals with opposite phases to each other are inputted;
a first differential output I-terminal from which the I_{P} signal is outputted, and a second differential output I-terminal from which the I_{N} signal is outputted;
a first differential output Q-terminal from which the Q_{P} signal is outputted, and a second differential output Q-terminal from which the Q_{N} signal is outputted;
a first mixer connected between the first differential input terminal and second differential input terminal and the first differential output I-terminal and second differential output I-terminal; and
a second mixer connected between the first differential input terminal and second differential input terminal and the first differential output Q-terminal and second differential output Q-terminal;
the acoustic wave device includes:
an I_{P} signal terminal and an I_{N} signal terminal;
a Q_{P} signal terminal and a Q_{N} signal terminal; and
a first differential terminal to receive an I signal phase-adjusted by the first phase shift circuit and a second differential terminal to receive a Q signal phase-adjusted by the second phase shift circuit;
the I_{P} signal terminal is connected to the first differential output I-terminal;
the I_{N} signal terminal is connected to the second differential output I-terminal;
the Q_{P} signal terminal is connected to the first differential output Q-terminal;
the Q_{N} signal terminal is connected to the second differential output Q-terminal;
in the acoustic wave device, where a phase rotation amount of the I signal transmitted from the I_{P} signal terminal and the I_{N} signal terminal to the first differential terminal is α°:
a phase rotation amount of the I_{P} signal transmitted from the I_{P} signal terminal to the first differential terminal is equal to or greater than (α+n×360−35.1)° and equal to or less than (α+n×360+35.1°); and
a phase rotation amount of the I_{N} signal transmitted from the I_{N} signal terminal to the first differential terminal is equal to or greater than (α+180+n×360−35.1)° and equal to or less than (α+180+n×360+35.1°);
when a value obtained by subtracting a phase of a local signal that drives the first mixer from a phase of a local signal that drives the second mixer is (+90+n×360)°, a relationship expressed as
$$( α - 90 + n \times 360 - 35.1 ) \leq β3 \leq ( α - 90 + n \times 360 + 35.1 ) ,$$
$$and$$
$$( α + 90 + n \times 360 - 35.1 ) \leq β4 \leq ( α + 90 + n \times 360 + 35.1 )$$
is satisfied;
when a value obtained by subtracting the phase of the local signal that drives the first mixer from the phase of the local signal that drives the second mixer is (−90+n×360)°, a relationship expressed as
$$( α + 90 + n \times 360 - 35.1 ) \leq β3 \leq ( α + 90 + n \times 360 + 35.1 ) ,$$
$$and$$
$$( α - 90 + n \times 360 - 35.1 ) \leq β4 \leq ( α - 90 + n \times 360 + 35.1 )$$
is satisfied, where β3° represents a phase rotation amount of the Q_{P} signal transmitted from the Q_{P} signal terminal to the second differential terminal, and β4° represents a phase rotation amount of the Q_{N} signal transmitted from the Q_{N} signal terminal to the second differential terminal.

15. The receiver according to claim 11, wherein
the I signal includes an I_{P} signal and an I_{N} signal in opposite phase to each other;
the Q signal includes a Q_{P} signal and a Q_{N} signal in opposite phase to each other;
the quadrature mixer includes:
a first differential input terminal and a second differential input terminal to which signals with opposite phases to each other are inputted;
a first differential output I-terminal from which the I_{P} signal is outputted, and a second differential output I-terminal from which the I_{N} signal is outputted;
a first differential output Q-terminal from which the Q_{P} signal is outputted, and a second differential output Q-terminal from which the Q_{N} signal is outputted;
a first mixer connected between the first differential input terminal and second differential input terminal and the first differential output I-terminal and second differential output I-terminal; and
a second mixer connected between the first differential input terminal and second differential input terminal and the first differential output Q-terminal and second differential output Q-terminal;
the acoustic wave device includes:
an I_{P} signal terminal and an I_{N} signal terminal;
a Q_{P} signal terminal and a Q_{N} signal terminal; and
a first differential terminal to receive an I signal phase-adjusted by the first phase shift circuit and a second differential terminal to receive a Q signal phase-adjusted by the second phase shift circuit;
the I_{P} signal terminal is connected to the first differential output I-terminal;
the I_{N} signal terminal is connected to the second differential output I-terminal;
the Q_{P} signal terminal is connected to the first differential output Q-terminal;
the Q_{N} signal terminal is connected to the second differential output Q-terminal;
in the acoustic wave device, where a phase rotation amount of the I signal transmitted from the I_{P} signal terminal and the I_{N} signal terminal to the first differential terminal is α°:
a phase rotation amount of the I_{P} signal transmitted from the I_{P} signal terminal to the first differential terminal is equal to or greater than (α+n×360−35.1)° and equal to or less than (α+n×360+35.1°); and
a phase rotation amount of the I_{N} signal transmitted from the I_{N} signal terminal to the first differential terminal is equal to or greater than (α+180+n×360−35.1)° and equal to or less than (α+180+n×360+35.1°);
when a value obtained by subtracting a phase of a local signal that drives the first mixer from a phase of a local signal that drives the second mixer is (+90+n×360)°, a relationship expressed as
$$( α + 90 + n \times 360 - 35.1 ) \leq β3 \leq ( α + 90 + n \times 360 + 35.1 ) ,$$
$$and$$
$$( α - 90 + n \times 360 - 35.1 ) \leq β4 \leq ( α - 90 + n \times 360 + 35.1 )$$
is satisfied;
when a value obtained by subtracting the phase of the local signal that drives the first mixer from the phase of the local signal that drives the second mixer is (−90+n×360)°, a relationship expressed as
$$( α - 90 + n \times 360 - 35.1 ) \leq β3 \leq ( α - 90 + n \times 360 + 35.1 ) ,$$
$$and$$
$$( α + 90 + n \times 360 - 35.1 ) \leq β4 \leq ( α + 90 + n \times 360 + 35.1 )$$
is satisfied, where β3° represents a phase rotation amount of the Q_{P} signal transmitted from the Q_{P} signal terminal to the second differential terminal, and β4° represents a phase rotation amount of the Q_{N} signal transmitted from the Q_{N} signal terminal to the second differential terminal.

16. A communication device comprising:
a signal processing circuit to process a radio-frequency signal; and
the receiver according to claim 10 to transmit the radio-frequency signal between the signal processing circuit and an antenna.

17. The communication device according to claim 16, wherein in the acoustic wave device, a relationship expressed as
$$( α + 90 + n \times 360 - 35.1 ) \leq β \leq ( α + 90 + n \times 360 + 35.1 )$$
$$or$$
$$( α - 90 + n \times 360 - 35.1 ) \leq β \leq ( α - 90 + n \times 360 + 35.1 )$$
is satisfied, where α° represents a phase rotation amount of the I signal, β° represents a phase rotation amount of the Q signal, and n is an integer.

18. The communication device according to claim 17, wherein
the I signal includes an I_{P} signal and an I_{N} signal in opposite phase to each other;
the Q signal includes a Q_{P} signal and a Q_{N} signal in opposite phase to each other;
the quadrature mixer includes:
a first differential input terminal and a second differential input terminal to which signals with opposite phases to each other are inputted;
a first differential output I-terminal from which the I_{P} signal is outputted, and a second differential output I-terminal from which the I_{N} signal is outputted;
a first differential output Q-terminal from which the Q_{P} signal is outputted, and a second differential output Q-terminal from which the Q_{N} signal is outputted;
a first mixer connected between the first differential input terminal and second differential input terminal and the first differential output I-terminal and second differential output I-terminal; and
a second mixer connected between the first differential input terminal and second differential input terminal and the first differential output Q-terminal and second differential output Q-terminal;
the acoustic wave device includes:
an I_{P} signal terminal and an I_{N} signal terminal;
a Q_{P} signal terminal and a Q_{N} signal terminal; and
an output terminal;
the I_{P} signal terminal is connected to the first differential output I-terminal;
the I_{N} signal terminal is connected to the second differential output I-terminal;
the Q_{P} signal terminal is connected to the first differential output Q-terminal;
the Q_{N} signal terminal is connected to the second differential output Q-terminal;
in the acoustic wave device, where a phase rotation amount of the I signal transmitted from the I_{P} signal terminal and the I_{N} signal terminal to the output terminal is α°:
a phase rotation amount of the I_{P} signal transmitted from the I_{P} signal terminal to the output terminal is equal to or greater than (α+n×360−35.1)° and equal to or less than (α+n×360+35.1)°; and
a phase rotation amount of the I_{N} signal transmitted from the I_{N} signal terminal to the output terminal is equal to or greater than (α+180+n×360−35.1)° and equal to or less than (α+180+n×360+35.1)°;
when a value obtained by subtracting a phase of a local signal to drive the first mixer from a phase of a local signal that drives the second mixer is (+90+n×360)°, a relationship expressed as
$$( α + 90 + n \times 360 - 35.1 ) \leq β1 \leq ( α + 90 + n \times 360 + 35.1 ) ,$$
$$and$$
$$( α - 90 + n \times 360 - 35.1 ) \leq β2 \leq ( α - 90 + n \times 360 + 35.1 )$$
is satisfied; and
when a value obtained by subtracting the phase of the local signal that drives the first mixer from the phase of the local signal that drives the second mixer is (−90+n×360)°, a relationship expressed as
$$( α - 90 + n \times 360 - 35.1 ) \leq β1 \leq ( α - 90 + n \times 360 + 35.1 ) ,$$
$$and$$
$$( α + 90 + n \times 360 - 35.1 ) \leq β2 \leq ( α + 90 + n \times 360 + 35.1 )$$
is satisfied, where β1° represents a phase rotation amount of the Q_{P} signal transmitted from the Q_{P} signal terminal to the output terminal, and β2° represents a phase rotation amount of the Q_{N} signal transmitted from the Q_{N} signal terminal to the output terminal.

19. The communication device according to claim 17, wherein
the I signal includes an I_{P} signal and an I_{N} signal in opposite phase to each other;
the Q signal includes a Q_{P} signal and a Q_{N} signal in opposite phase to each other;
the quadrature mixer includes:
a first differential input terminal and a second differential input terminal to which signals with opposite phases to each other are inputted;
a first differential output I-terminal from which the I_{P} signal is outputted, and a second differential output I-terminal from which the I_{N} signal is outputted;
a first differential output Q-terminal from which the Q_{P} signal is outputted, and a second differential output Q-terminal from which the Q_{N} signal is outputted;
a first mixer connected between the first differential input terminal and second differential input terminal and the first differential output I-terminal and second differential output I-terminal; and
a second mixer connected between the first differential input terminal and second differential input terminal and the first differential output Q-terminal and second differential output Q-terminal;
the acoustic wave device includes:
an I_{P} signal terminal and an I_{N} signal terminal;
a Q_{P} signal terminal and a Q_{N} signal terminal; and
an output terminal;
the I_{P} signal terminal is connected to the first differential output I-terminal;
the I_{N} signal terminal is connected to the second differential output I-terminal;
the Q_{P} signal terminal is connected to the first differential output Q-terminal;
the Q_{N} signal terminal is connected to the second differential output Q-terminal;
in the acoustic wave device, where a phase rotation amount of the I signal transmitted from the I_{P} signal terminal and the I_{N} signal terminal to the output terminal is α°:
a phase rotation amount of the I_{P} signal transmitted from the I_{P} signal terminal to the output terminal is equal to or greater than (α+n×360−35.1)° and equal to or less than (α+n×360+35.1)°; and
a phase rotation amount of the I_{N} signal transmitted from the I_{N} signal terminal to the output terminal is equal to or greater than (α+180+n×360-35.1)° and equal to or less than (α+180+n×360+35.1)°;
when a value obtained by subtracting a phase of a local signal that drives the first mixer from a phase of a local signal that drives the second mixer is (+90+n×360)°, a relationship expressed as
$$( α - 90 + n \times 360 - 35.1 ) \leq β1 \leq ( α - 90 + n \times 360 + 35.1 ) ,$$
$$and$$
$$( α + 90 + n \times 360 - 35.1 ) \leq β2 \leq ( α + 90 + n \times 360 + 35.1 )$$
is satisfied; and
when a value obtained by subtracting the phase of the local signal that drives the first mixer from the phase of the local signal that drives the second mixer is (−90+n×360)°, a relationship expressed as
$$( α + 90 + n \times 360 - 35.1 ) \leq β1 \leq ( α + 90 + n \times 360 + 35.1 ) ,$$
$$and$$
$$( α - 90 + n \times 360 - 35.1 ) \leq β2 \leq ( α - 90 + n \times 360 + 35.1 )$$
is satisfied, where β1° represents a phase rotation amount of the Q_{P} signal transmitted from the Q_{P} signal terminal to the output terminal, and β2° represents a phase rotation amount of the Q_{N} signal transmitted from the Q_{N} signal terminal to the output terminal.

20. The communication device according to claim 17, wherein
the I signal includes an I_{P} signal and an I_{N} signal in opposite phase to each other;
the Q signal includes a Q_{P} signal and a Q_{N} signal in opposite phase to each other;
the quadrature mixer includes:
a first differential input terminal and a second differential input terminal to which signals with opposite phases to each other are inputted;
a first differential output I-terminal from which the I_{P} signal is outputted, and a second differential output I-terminal from which the I_{N} signal is outputted;
a first differential output Q-terminal from which the Q_{P} signal is outputted, and a second differential output Q-terminal from which the Q_{N} signal is outputted;
a first mixer connected between the first differential input terminal and second differential input terminal and the first differential output I-terminal and second differential output I-terminal; and
a second mixer connected between the first differential input terminal and second differential input terminal and the first differential output Q-terminal and second differential output Q-terminal;
the acoustic wave device includes:
an I_{P} signal terminal and an I_{N} signal terminal;
a Q_{P} signal terminal and a Q_{N} signal terminal; and
a first differential terminal to receive an I signal phase-adjusted by the first phase shift circuit and a second differential terminal to receive a Q signal phase-adjusted by the second phase shift circuit;
the I_{P} signal terminal is connected to the first differential output I-terminal;
the I_{N} signal terminal is connected to the second differential output I-terminal;
the Q_{P} signal terminal is connected to the first differential output Q-terminal;
the Q_{N} signal terminal is connected to the second differential output Q-terminal;
in the acoustic wave device, where a phase rotation amount of the I signal transmitted from the I_{P} signal terminal and the I_{N} signal terminal to the first differential terminal is α°:
a phase rotation amount of the I_{P} signal transmitted from the I_{P} signal terminal to the first differential terminal is equal to or greater than (α+n×360−35.1)° and equal to or less than (α+n×360+35.1°); and
a phase rotation amount of the I_{N} signal transmitted from the I_{N} signal terminal to the first differential terminal is equal to or greater than (α+180+n×360−35.1)° and equal to or less than (α+180+n×360+35.1°);
when a value obtained by subtracting a phase of a local signal that drives the first mixer from a phase of a local signal that drives the second mixer is (+90+n×360)°, a relationship expressed as
$$( α - 90 + n \times 360 - 35.1 ) \leq β3 \leq ( α - 90 + n \times 360 + 35.1 ) ,$$
$$and$$
$$( α + 90 + n \times 360 - 35.1 ) \leq β4 \leq ( α + 90 + n \times 360 + 35.1 )$$
is satisfied;
when a value obtained by subtracting the phase of the local signal that drives the first mixer from the phase of the local signal that drives the second mixer is (−90+n×360)°, a relationship expressed as
$$( α + 90 + n \times 360 - 35.1 ) \leq β3 \leq ( α + 90 + n \times 360 + 35.1 ) ,$$
$$and$$
$$( α - 90 + n \times 360 - 35.1 ) \leq β4 \leq ( α - 90 + n \times 360 + 35.1 )$$
is satisfied, where β3° represents a phase rotation amount of the Q_{P} signal transmitted from the Q_{P} signal terminal to the second differential terminal, and β4° represents a phase rotation amount of the Q_{N} signal transmitted from the Q_{N} signal terminal to the second differential terminal.
